(19) United States
(12) Patent Application Publication
(10) Pub. No.: US 2009/0174578 A1
(43) Pub. Date: Jul. 9, 2009

(54) Operating apparatus and operating system

(75) Inventor: Kazunari Taki, Nagoya-shi (JP)

Correspondence Address: OLIFF & BERRIDGE, PLC, P.O. BOX 320850, ALEXANDRIA, VA, 22320-4850, US

(73) Assignee: BROTHER KOGYO KABUSHIKI KAISHA, NAGOYA-SHI (JP)

(21) Appl. No.: 12/320,185

(22) Filed: Jan. 21, 2009

Related U.S. Application Data
(63) Continuation-in-part of application No. PCT/JP2007/064378, filed on Jul. 20, 2007.

(30) Foreign Application Priority Data
Jul. 21, 2006 (JP) 2006-200105
Jul. 21, 2006 (JP) 2006-200106

(51) Int. Cl. H03K 17/94; G01B 11/14

(52) U.S. Cl. 341/20; 356/614; 356/51

(57) ABSTRACT

An operating apparatus has a ring body to be mounted on a human body so that an irradiation light emitted from LED is irradiated to a part of the human body of an operator and a plurality of photodetectors configured to receive scattering light or transmission light irradiated to a part of the human body at an irradiation portion, and on the basis of a combination of a light receiving result of the irradiation light at these plurality of photodetectors, an operation signal corresponding to an operation state of the operator is outputted.

### CROSS-REFERENCE TO RELATED APPLICATION

This is a CIP application PCT/JP2007/064378, filed Jul. 20, 2007, which was not published under PCT article 21(2) in English.

### BACKGROUND OF THE INVENTION

1. Field of the Invention

The present invention relates to an operating apparatus and an operating system that can output a corresponding operation signal to an operation target by being mounted on an operator at a predetermined portion and moved.

2. Description of the Related Art

As an apparatus that is mounted on a human body of an operator and outputs an operation signal corresponding to an operation state of the operator, the one described in JP, A, 11-338597 is known, for example.

In this prior art, a plurality of acceleration sensors are provided on an inner face of amounting device (band) mounted on a wrist of an operator for detecting an impact or acceleration by finger hitting operation of a finger tip of a hand of the operator and a command or character corresponding to the finger hitting operation is recognized on the basis of a detection result and outputted.

In the above prior art, since the operation of a finger tip of the operator is detected by the acceleration sensor inside the wrist, it is necessary to bring the sensor into close contact with the portion of the operator in order to accurately detect the acceleration, and there is a problem that a sense of pressure or discomfort can be given to the operator.

There is a method of measuring myoelectric potential of the operator at the mounted portion instead of acceleration detection, but in this case, too, an electrode for measurement should be brought into close contact with the mounted portion of the operator, which leads to the same problem.

### SUMMARY OF THE INVENTION

An object of the present invention is to provide an operating apparatus and an operating system that can realize an operation reflecting an intension of the operator with high accuracy without giving a sense of pressure or discomfort to the operator during mounting.

### BRIEF DESCRIPTION OF THE DRAWING

FIG. 1 is an explanatory diagram illustrating entire configuration of an operating system including the operating apparatus according to a first embodiment of the present invention.

FIG. 2 is a perspective view illustrating a detailed structure of the operating apparatus.

FIG. 3 is a view on arrow seen from A direction in FIG. 2.

FIGS. 4A and 4B are diagrams illustrating an example of a light-receiving behavior of irradiation light.

FIG. 5 is a diagram conceptually illustrating a detection method of attitude change of the hand.

FIG. 6 is a functional block diagram illustrating a control system including a detection controller provided at the operating apparatus.

FIG. 7 is a flowchart illustrating an example of a control procedure executed by a detection control part.

FIG. 8A is an explanatory diagram for explaining an example of a light-receiving pattern table with the light-receiving pattern at each offset position of k=0 to 15.

FIG. 8B is an explanatory diagram illustrating an example of actually detected values to be checked. FIG. 8C is a diagram for explaining a method of detecting a current position in the rotating direction of a ring body finally.

FIG. 9 is a flowchart illustrating a detailed procedure of Step S200.

FIG. 10 is a flowchart illustrating a detailed procedure of Step S300.

FIG. 11 is a flowchart illustrating a detailed procedure of Step S400.

FIG. 12 is a functional block diagram illustrating functional configuration of a controller.

FIG. 13 is a flowchart illustrating an example of a control procedure executed by the entire controller.

FIG. 14 is a perspective view illustrating a detailed appearance structure of a display device.

FIG. 15 is an explanatory diagram illustrating an example in which the operating system is actually utilized.

FIG. 16 is a diagram illustrating a variation of simultaneous light emission using a filter device.

FIG. 17 is a diagram illustrating another variation of simultaneous light emission using a filter device.

FIG. 18 is a conceptual explanatory diagram illustrating a method and principle of a neural network.

FIG. 19 is a functional block diagram illustrating a control system of a variation in which attitude analysis is conducted on the operating apparatus side.

FIG. 20 is an explanatory diagram illustrating entire configuration of the operating system including the operating apparatus in a second embodiment of the present invention.

FIG. 21 is a front view illustrating a detailed structure of the operating apparatus.

FIG. 22 is a diagram illustrating a state where the operating apparatus is mounted on a wrist of an operator.

FIGS. 23A and 23B are diagrams illustrating an example of a light-receiving behavior of irradiation light in the operating apparatus.

FIGS. 24A to 24D are diagrams illustrating an example of a reflection light and scattering light pattern detected by a photodetector.

FIG. 25 is a functional block diagram illustrating a control system including a detection controller.

FIG. 26 is a flowchart illustrating an example of a control procedure executed by the detection control part.

FIG. 27 is a flowchart illustrating a detailed procedure of Step S200 in FIG. 26.

FIG. 28 is a flowchart illustrating a detailed procedure of Step S300′ in FIG. 26.

FIG. 29 is a flowchart illustrating a detailed procedure of Step S400′ in FIG. 26.

FIG. 30 is a flowchart illustrating an example of the control procedure executed by the entire controller.

FIG. 31 is a functional block diagram illustrating a control system including a detection controller provided in a variation of simultaneous light-emission using the filter device.

FIG. 32 is a functional block diagram illustrating a control system including the detection controller provided in another variation of simultaneous light-emission using the filter device.

FIG. 33 is a functional block diagram illustrating a control system in the variation in which the attitude analysis is also conducted at the operating apparatus.

### DETAILED DESCRIPTION OF THE PREFERRED EMBODIMENTS

Embodiments of the present invention will be described below referring to the attached drawings.

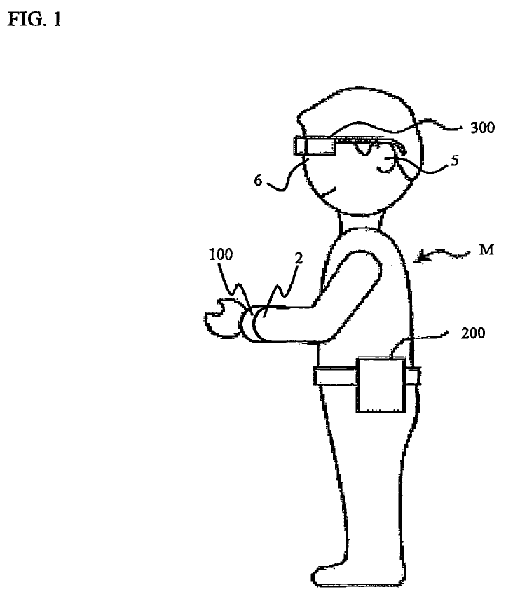

A first embodiment of the present invention will be described referring to FIGS. 1 to 19. This embodiment is an embodiment of an operating apparatus for irradiating light to a wrist side of an operator.

FIG. 1 is an explanatory diagram illustrating entire configuration of an operating system including the operating apparatus according to this embodiment.

In FIG. 1, this system has an operating apparatus 100 used by mounting on a predetermined mounted portion (a wrist 2 in this example) in a body of an operator M, a controller 200 held at a hip 3 of the operator M through a belt 4 in this example and provided with a calculating device such as a CPU and the like, for example, and a display device 300 (head-mount display) mounted from ears 5 to a nose 6 of the operator M like glasses.

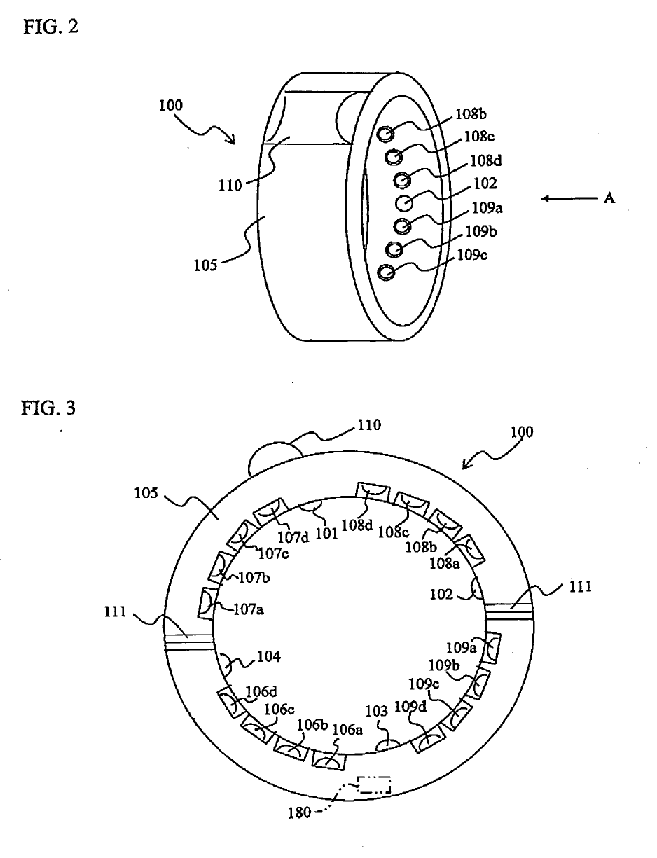

FIG. 2 is a perspective view illustrating a detailed structure of the above operating apparatus 100 and FIG. 3 is a view on arrow seen from A direction in FIG. 2.

In FIGS. 2 and 3, the operating apparatus 100 is provided with a substantially annular shape and has a ring body 105 (mounting device) mounted on the wrist 2 of the operator M (with a slight gap so as to be rotatable, as will be described later). At the ring body 105 (on the inner circumference side in the radial direction in this example), at least one (four pieces in this example) LED (light-emitting device) 101, 102, 103, 104 emitting predetermined irradiation light, and corresponding at least one set (four pairs in this example) of photodetectors (light receiving device. A photodiode, phototransistor, CCD, CMOS sensor and the like, for example) 106a to 106d, 107a to 107d, 108a to 108d, 109a to 109d are provided and moreover, at the ring body 105 (on the outer circumference side in the radial direction in this example), a detection controller 110 constituted by a calculating device such as a CPU and the like, for example, that controls the above LEDs 101 to 104 and the photodetectors 106 to 109 and performs predetermined detection processing (details will be described later) and a size adjusting portion 111 in an elastic structure, for example, so as to respond to a difference in the size of the wrist 2 due to the body build of the operator M are provided.

As the irradiation light from the LEDs 101, 102, 103, 104, light with the wavelength included in a visible light band to a near infrared light band can be emitted, for example. The near infrared light has relatively high translucency to a living tissue, and hemoglobin in the living tissue has a characteristic absorption spectrum in the near infrared light band. Therefore, by emitting the irradiation light in the near infrared band from the LEDs 101 to 104, change in scattering or change in blood flow distribution in a tissue of the mounted portion (a wrist portion involved in movement of a finger, for example) involved in an operation of the operating portion of the operator M can be detected by a light-receiving behavior of the near infrared light by the photodetectors 106a to 106d, 107a to 107d, 108a to 108d, 109a to 109d.

In addition, the green or blue wavelength in the visible light away from the near infrared light has a nature of being reflected/scattered by a skin, and by emitting the irradiation light with the green or blue wavelength from the LEDs 101 to 104, a shape change on the skin surface at the operating portion involved in the operation of the operator M can be detected by the light-receiving behavior of the visible light (change in light receiving sensitivity) by the photodetectors 106a to 106d, 107a to 107d, 108a to 108d, 109a to 109d.

The light-emitting behavior of the LEDs 101 to 104 at this time may be emission of the same irradiation light included in the near infrared band by each LED, respectively. In this case, by using the irradiation light with the single wavelength, there is no need to prepare plural types of LEDs, which can reduce manufacturing costs and simplify control. Alternatively, at least one of the LEDs 101 to 104 is made to have a wavelength included in the near infrared band while the irradiation light with the plural wavelengths is emitted as a whole. By using the irradiation light with the plural wavelength as above, detection mainly using the permeability of the living tissue and the detection using the reflection/scattering mainly on the skin can be used at the same time, and received-light detection can be made with higher accuracy.

Further, LED emitting light with plural wavelengths, that is, a plurality of LEDs in which a near infrared light emitting LED and a visible light emitting LED are contained in a single LED package may be used. Alternatively, instead of the LED, a laser diode (LD) may be used.

The ring body 105 has the above four LEDs 101 to 104 disposed in the circumferential direction (with an equal interval in this example) and is mounted so that the irradiation light emitted from the LEDs 101 to 104 is irradiated to a part of the human body of the operator M (the wrist 2 in this example). At this time, the light-emitting elements 106a to 106d, 107a to 107d, 108a to 108d, 109a to 109d are provided in correspondence with the arrangement of the above LEDs 101, 102, 103, 104 so that the scattering light (or transmission light. Details will be described later) at the irradiation portion of the irradiation light irradiated from the LEDs 101 to 104 to the part of the human body of the operator M (the wrist 2 in this example) is received. As a result, the LEDs 101 to 104 and the photodetectors 106a to 106d, 107a to 107d, 108a to 108d, 109a to 109d are arranged in the substantially annular state with respect to the ring body 105. In addition, at this time, a light-emitting/light-receiving device group consisting of the light-receiving side LEDs and the corresponding photodetectors, that is, the LED 101 and the photodetectors 106a to 106d, the LED 102 and the photodetectors 107a to 107d, the LED 103 and the photodetectors 108a to 108d, and the LED 104 and 109a to 109d are arranged so that each group is located in rotation symmetry to each other.

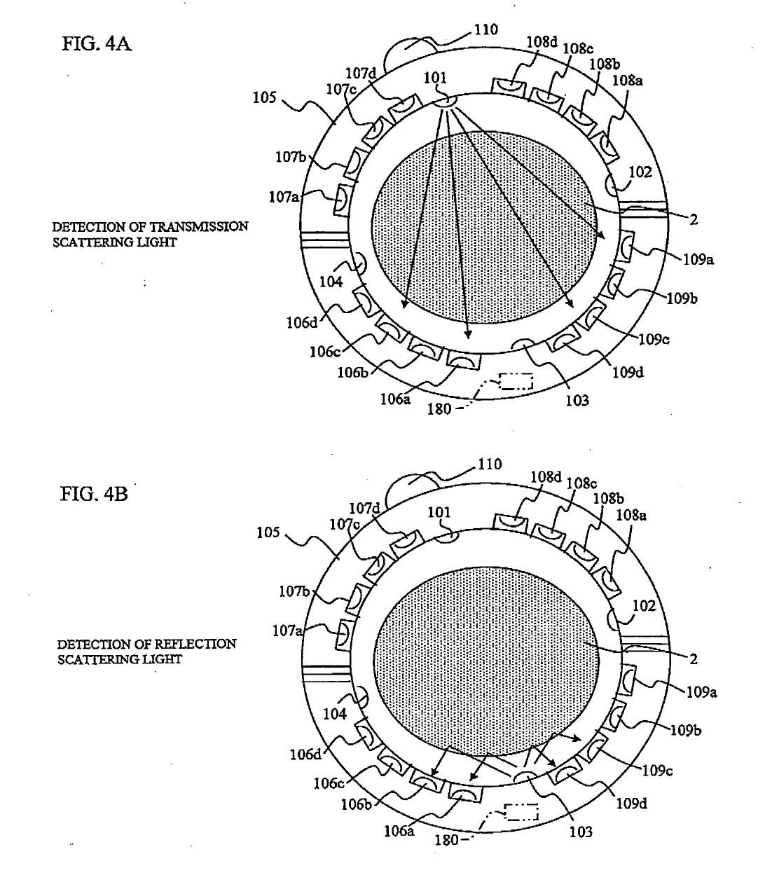

FIGS. 4A and 4B are diagrams illustrating an example of the light-receiving behavior of such irradiation light. The example shown in FIG. 4A illustrates such a state that transmission scattering light at the wrist 2 of the irradiation light illuminated from the LED 101 is received by the photodetectors 106a to 106d, 109a to 109d and the like arranged in an opposed manner with the wrist 2 held between them with respect to the LED 101 (movement of a blood vessel of the wrist 2 is mainly detected). The example shown in FIG. 4B illustrates such a state that the reflection scattering light at the wrist 2 of the irradiation light illuminated from the LED 103 is received by the photodetectors 106a, 106b, 109d, 109c and the like arranged in the vicinity in the circumferential direction of the LED 103 (movement of the skin surface of the wrist 2 is mainly detected).

As shown in the examples in FIGS. 4A and 4B, in this embodiment, the transmission scattering light or reflection scattering light at the wrist 2 of the irradiation light illuminated from at least one of the LEDs 101, 102, 103, 104 is received by the corresponding photodetectors 101a to 106d, 107a to 107d, 108a to 108d, 109a to 109d, and the hand attitude or change in the attitude of the operator M is detected by the pattern of the light receiving result.

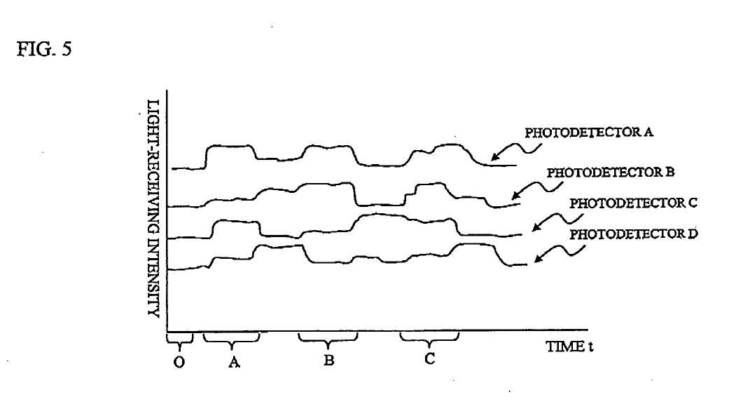

FIG. 5 is a diagram conceptually illustrating a detection method of the attitude change of the hand and shown with time on the lateral axis and a conceptual detected light-receiving intensity on the vertical axis. In FIG. 5, in this example, for facilitation of understanding, the light-receiving behavior when the operator M takes one of three attitudes of “stone”, “paper”, “scissors” is conceptually illustrated.

That is, at a time “O” in the figure, a natural state where the operator M does not make any particular operation is shown, at a time “A” in the figure, a so-called “paper” state where the five fingers are all stretched is shown, at a time “B” in the figure, a so-called “scissors” state where the thumb, the fourth finger and the little finger are folded to the palm side from the above “paper” state is shown, and at a time “C” in the figure, a so-called “stone” state where the forefinger and the middle finger are also folded to the palm side from the “scissors” state is shown. Since the positions and states of the muscle, blood vessel and the like of the wrist 2 of the operator M are changed in coordination by movement of each finger as above, the behavior of the above-mentioned transmission scattering light or reflection scattering light is changed, and as a result, each light-receiving intensity at the photodetectors A to D (any of the photodetectors 106a to 106d, 107a to 107d, 108a to 108d, 109a to 109d) is temporally changed as shown, and by analyzing the change pattern with a predetermined method, the attitude of the hand of the operator M or its change can be detected. Instead of watching the light-receiving intensity, pulse light may be illuminated so as to detect its attenuated value, for example.

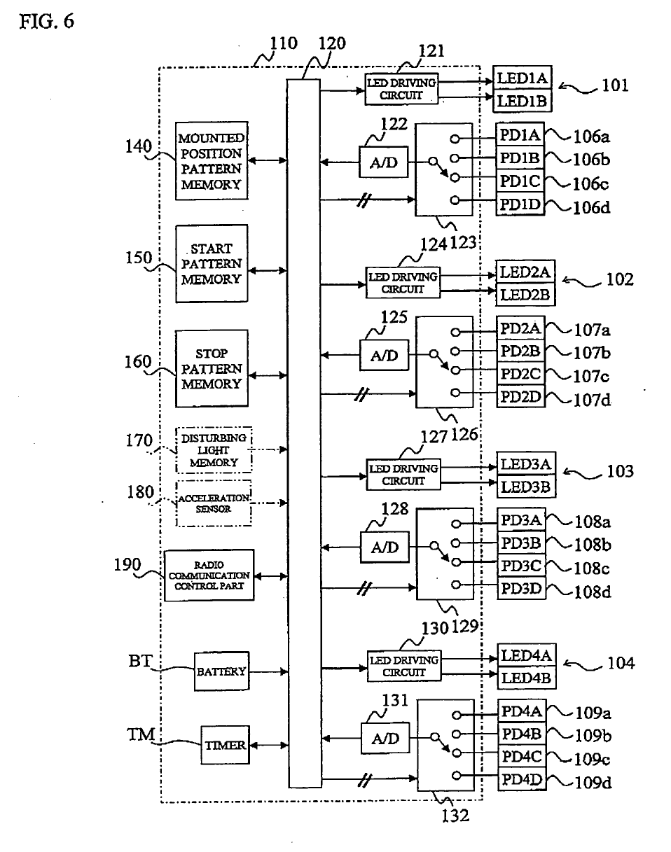

FIG. 6 is a functional block diagram illustrating a control system including the detection controller 110 provided at the operating apparatus 100 for realizing the above method.

In FIG. 6, the detection controller 110 comprises a detection control part 120, LED driving circuits 121, 124, 127, 130 for driving the LEDs 101, 102, 103, 104 on the basis of a control signal from the detection control part 120, switches 123, 126, 129, 132 for selectively inputting four output signals (light-receiving signals) each of the photodetectors 106a to 106d, 107a to 107d, 108a to 108d, 109a to 109d, A/D converters 122, 125, 128, 131 for digital-conversion an input signal selected at the switches 123, 126, 129, 132, respectively, and outputting them to the detection control part 120, a mounted position pattern memory 140 used for specifying a mounted position of the ring body 105 capable of relative rotation with respect to the wrist 2 (details will be described later), a start pattern memory 150 and a stop pattern memory 160 used for recognizing a detection-start or -end trigger signal (details will be described later), a radio communication control part 190 configured to carry out radio communication with the controller 200, provided with a known antenna, a communication circuit and the like, a battery BT for power supply, and a timer TM.

In the LEDs 101, 102, 103, 104, those with different wavelength or LED1A, LED2A, LED3A, LED4A, which are visible light LEDs in this example, and LED1B, LED2B, LED3B, LED4B, which are near infrared light LEDs, are contained in a single package, respectively. At the visible light LED and the infrared light LED, the visible light emission and near infrared light emission may be switched by the respective driving circuits 121, 124, 127, 130 as will be described later (or they may be emitted at the same time if they can be separated by a filter in a variation, which will be described later).

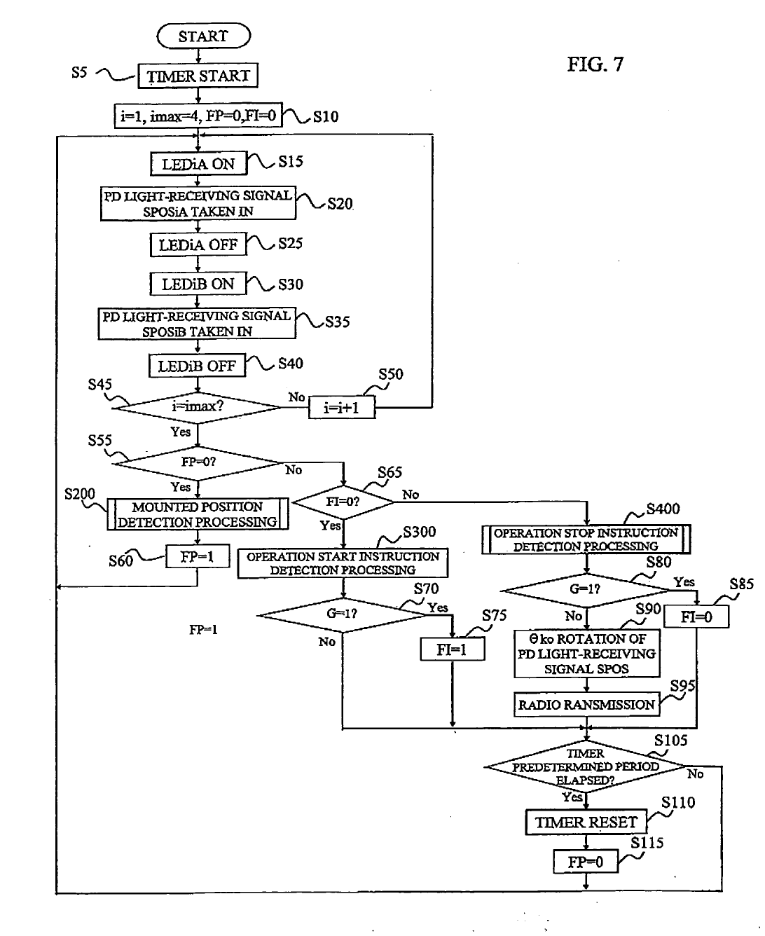

FIG. 7 is a flowchart illustrating an example of a control procedure executed by the detection control part 120. In FIG. 7, first, at Step S5, count of the timer TM is started.

Subsequently, the routine goes to Step S10, where a variable for specifying the light-emitting/light-receiving order of a plurality of (four in this example) LED and corresponding plural pairs (four pairs in this example) of photodetectors is initialized to i=1, its maximum value is set at imax=4 in this example, a mode flag (a flag indicating if in an operation mode or in a mounted position detection mode. Details will be described later) is initialized to FP=0, and an operation flag (a flag indicating if being operation input or waiting for operation start instruction in the operation mode. Details will be described later) is initialized to FI=0.

After that, the routine goes to Step S15, where a control signal is outputted to the LED driving circuits 121, 125, 128, 131 corresponding to the i-th LEDs 101 to 104 so as to start light emission of the LEDs 101 to 104. At this time, in this example, as shown in FIG. 6, each of the LEDs 101 to 104 is provided with two LEDs with wavelengths different from each other (visible light LED and near infrared light LED in the above-mentioned example) as a pair such as first and second LED 101a (indicated by “LED1A” in FIG. 6), 101b (indicated by “LED1B” in FIG. 6), first and second LED 102a(indicated by “LED2A” in FIG. 6), 102b (indicated by “LED2B” in FIG. 6), first and second LED 103a (indicated by “LED3A” in FIG. 6), 103b (indicated by “LED3B” in FIG. 6), first and second LED 104a (indicated by “LED4A” in FIG. 6), 104b (indicated by “LED4B” in FIG. 6). At Step S15, light of a corresponding one in the i-th first LED101a, 102a, 103a, 104a (since the first one is i=1, it is LED101a) is emitted.

Subsequently, the routine goes to Step S20, where a light-receiving result signal SposiA at each of the photodetectors 106a to 106d, 107a to 107d, 108a to 108d, 109a to 109d by light emission of the first LED101a, 102a, 103a, 104a at Step S15 is taken in (and temporarily stored in an appropriate memory device). That is, the light-receiving signal at the photodetectors 106a, 106b, 106c, 106d is sequentially taken in through the A/D converter 122 while the switch 123 is switched, the light-receiving signal at the photodetectors 107a, 107b, 107c, 107d is sequentially taken in through the A/D converter 125 while the switch 126 is switched, the light-receiving signal at the photodetectors 108a, 108b, 108c, 108d is sequentially taken in through the A/D converter 128 while the switch 129 is switched, and the light-receiving signal at the photodetectors 109a, 109b, 109c, 109d is sequentially taken in through the A/D converter 131 while the switch 132 is switched (therefore, in this example, 16 light-receiving signals are taken in for light emission of single first LED 101a, 102a, 103a, 104a).

Subsequently, the routine goes to Step S25, where a control signal is outputted to the LED driving circuits 121, 125, 128, 131 corresponding to the i-th LEDs 101 to 104 at which light emission is started at Step S15, and the light emission of the first LED 101a, 102a, 103a, 104a is stopped.

Subsequently, the routine goes to Step S30, where similarly to Step S15, a control signal is outputted to the LED driving circuits 121, 125, 128, 131, and light emission of a corresponding one of the i-th second LED 101b, 102b, 103b, 104b (since it is i=1 at first, LED 101b) is started.

And at Step S35, similarly to Step S20, the light-receiving result signal SposiB at each of the photodetectors 101a to 106d, 107a to 107d, 108a to 108d, 109a to 109d by light emission of the second LED 101a, 102a, 103a, 104a at Step S30 is sequentially taken in through the A/D converters 122, 125, 128, 131 while the switches 123, 126, 129, 132 are sequentially switched (similarly to the above, 16 light-receiving signals are taken in for the single second LED 101b, 102b, 103b, 104b and temporarily stored in an appropriate memory device).

Subsequently, the routine goes to Step S40, where a control signal is outputted to the LED driving circuits 121, 125, 128, 131 corresponding to the i-th LEDs 101 to 104 at which light emission is started at Step S30 and light emission of the second LED 101b, 102b, 103b, 104b is stopped.

And at Step S45, it is determined if a value of i becomes imax (i=4 in this example) or not. In the case of i<imax, the determination is not satisfied, 1 is added to the value of at Step S50 (in other words, the order of the LED is changed to the subsequent one), the routine returns to Step S15, and light emission at the first LED 101a, 102a, 103a, 104a and the second LED 101b, 102b, 103b, 104b and light receiving at the photodetectors 106a to 106d, 107a to 107d, 108a to 108d, 109a to 109d are similarly repeated at Step S15 to Step S45.

The light emission and light receiving are repeated as above, and when light emission of the first LED 104a and the second LED 104b with i=4 and light receiving at the photodetectors 106a to 106d, 107a to 107d, 108a to 108d, 109a to 109d are finished, the determination at Step S45 is satisfied, and the routine goes to Step S55. At this time, light may be emitted with time difference for each loop with a predetermined time interval when the routine returns from Step S45 to Step S15 through Step S50 (time-difference light emission control portion). By sequential light emission with a time difference instead of the same light emission, separation processing and the like of the irradiation light received at the photodetectors 106a to 106d, 107a to 107d, 108a to 108d, 109a to 109d is not needed any more, which can facilitate processing and control and reduce manufacturing costs and the like.

At Step S55, it is determined if the mode flag FP=0 or not. First, since FP=0 at Step S10, the determination is satisfied, and the routine goes to Step S200.

At Step S200, on the basis of check between a light-receiving pattern taken in by repeating Step S15 to Step S40 as above four times (in this example) and a pattern stored in the mounted position pattern memory 140 (details will be described later), mounted position detection processing for detecting a relative position of the ring body 105 attached to the wrist 2 (position in the rotating direction around the wrist 2) is executed so as to determine a mounted position (attached angle) in the rotating direction θko (details will be described later).

When the detection processing of the mounted position of the ring body 105 is completed at Step S200, the mode flag FP is changed to FP=1, which is an operation mode, at Step S60, and the routine returns to Step S15. And after the light-receiving result is taken in by repeating Step S15 to Step S40 four times again similarly to the above, since it is FP=1, the determination is not satisfied any more at Step S55, and the routine goes to Step S65.

At Step S65, it is determined if it is still the operation flag FI=0. First, since it is FI=0 as in the state initialized at the previous Step S10, the determination is satisfied, and the routine goes to Step S300.

At Step S300, on the basis of the check between the light-receiving pattern taken in by repeating Step S15 to Step S40 as above four times (in this example) and a pattern stored in the start pattern memory 150 (details will be described later), operation start instruction detection processing for detecting if an operation of (a finger of, in this case) the operator M is intended to start an operation is executed.

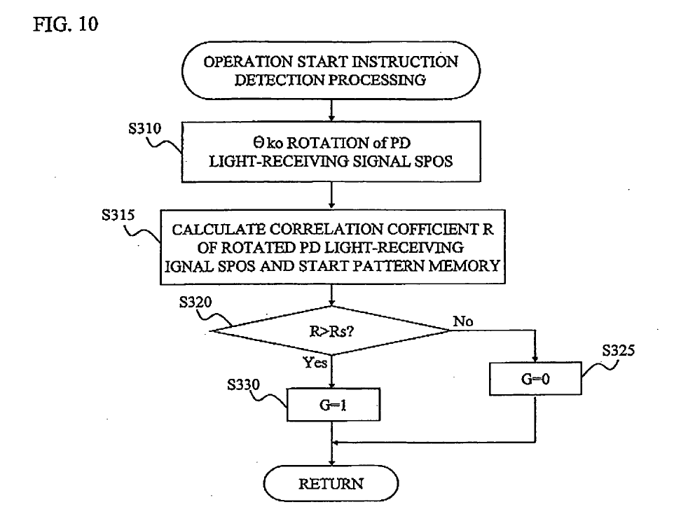

Subsequently, the routine goes to Step S70, where it is determined if a flag G indicating recognition/unrecognition of instruction is 1 or not. If the operation start instruction has been recognized at Step S300, it is G=1 (See Step S330 in FIG. 10, which will be described later) and the determination is satisfied, the operation flag FI is changed at Step S75 to 1 indicating that the operation is being inputted, and the routine goes to Step S105. If the operation start instruction is unrecognition at Step S300, since it is G=0 (See Step S325 in FIG. 10, which will be described later), the determination is not satisfied and the routine goes to Step S105 as it is. As above, by detecting if the operation start is intended or not, a risk of detecting a usual finger movement and giving an unintended operation input instruction to erroneously operate the target is eliminated. Further, since the operation input is enabled only when a predetermined operation is detected, the operation input can be made only when necessary and an unintended operation at the other occasions can be prevented.

At Step S105, it is determined if a predetermined time set in advance (such time that if this time has elapsed, all the light-receiving results so far should be reset and an operation should be started again from detection of the mounted position, for example) has elapsed or not since time count by the timer TM at Step S5 is started. The determination is not satisfied till the time has elapsed, and the routine returns to Step S15, where the same procedure is repeated. If the operation start instruction is not recognized yet at Step S300 and it is still G=0, Step S105->repetition of Step S15 to Step S40 is made four times->Step S55->Step S65 and then, at Step S330, the operation start instruction is detected again and while the predetermined time has not elapsed yet, these procedures are repeated till the operation start instruction is recognized and it becomes G=1.

If it becomes G=1 by recognition of the operation start instruction, since it is FI=1 at Step S75, the routine returns to Step S15 as above, Step S15 to Step S40 are repeated four times->Step 55 and the determination at Step S65 is not satisfied and the routine goes to Step S400.

At Step S400, on the basis of the check between the light-receiving pattern taken in by repeating Step S15 to Step S40 four times (in this example) as above and the pattern stored in the stop pattern memory 160 (details will be described later), the operation stop instruction detection processing for detecting if the operation (of the finger in this example) by the operator M is intended to stop the operation or not is executed.

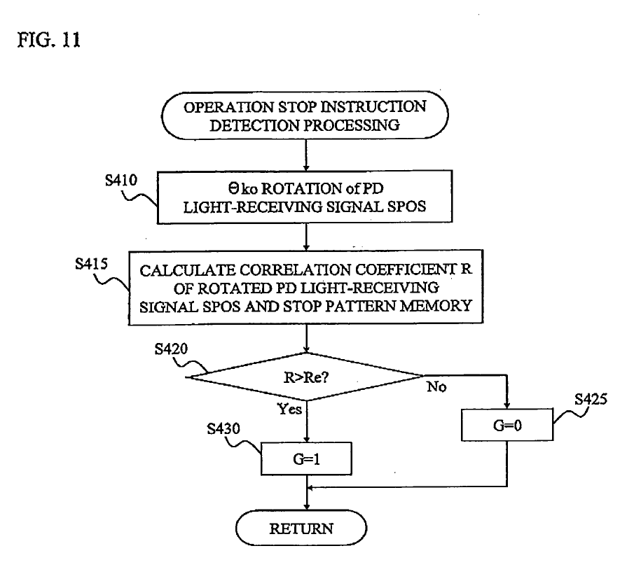

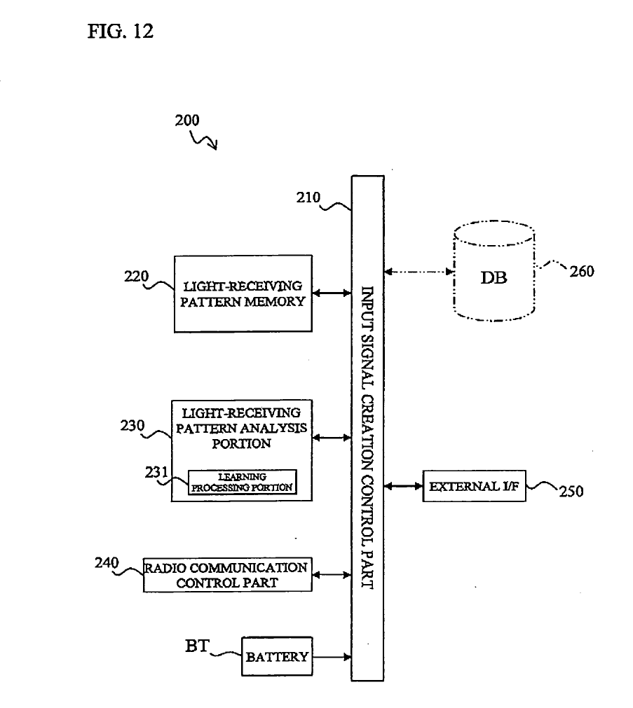

Subsequently, the routine goes to Step S80, where it is determined if the flag G indicating recognition/unrecognition of the instruction is 1 or not. If the operation stop instruction has not been recognized yet at Step S400, since it is G=0 (See Step S425 in FIG. 11, which will be described later), the determination is not satisfied and the routine goes to Step S90.

At Step S90, light-receiving result signals SposiA and SposiB obtained for i=1 to imax (four in this example) by four-times repetition of Step S15 to Step S40 before operation stop instruction after operation start instruction are considered to be the original operation manipulation corresponding to the operation intension of the operator M, correction is made so that rotation is carried out only by the attached angle θko detected at Step S200 and a light-receiving correction signal is created.

Subsequently, at Step S95, a control signal is outputted to the radio communication control part 190 and the light-receiving correction signal created at Step S90 is transmitted to the controller 200 via radio communication and the routine goes to Step S105.

On the other hand, if the operation stop instruction is recognized at Step S400 at the above-mentioned Step S80, since it is G=1 (See Step S430 in FIG. 11, which will be described later), the determination is satisfied, the operation flag FI is returned to Oat Step S85, indicating that the operation start instruction is awaited, and the routine goes to Step S105. By giving the operation stop instruction as above, if manipulation other than input is to be made by fingers and the like, there is no fear that an erroneous operation is inputted (giving an unintended operation signal by sending an unintended light-receiving correction signal to the controller) at the same time.

At Step S105, the determination is not satisfied till the above-mentioned predetermined time has elapsed, and the routine returns to Step S15 and the same procedure is repeated. And after Step S105->four-times repetition of Step 15 to Step S40->Step 55, the determination at Step S65 is satisfied, the operation start instruction is detected again at Step S330, and these procedures are repeated till the operation start instruction is recognized while the above predetermined time has not elapsed.

If the above-mentioned time count by the timer TM reaches the above predetermined time while the procedure from Step S15 to Step S105 as above is repeated, the determination at Step S105 is satisfied (=time over), the routine goes to Step S110, where a control signal is outputted to the timer TM so as to reset (initialize) the time count and then, in order to start from the detection of the mounted position again, it is returned to the mode flag FP=0 at Step S115, and the routine returns to Step S15 and same procedure is repeated. As a result, with the operation manipulation, the mounted position is changed such as rotation of the operating apparatus around the mounted portion, and by detecting the mounted portion regularly, the operation manipulation can be detected with high accuracy without giving discomfort to the wearer caused by close fixation to the mounted portion.

Subsequently, the mounted position detection processing at Step S200 will be described. In this embodiment, distribution of light receiving signals of irradiation light (light-receiving pattern) from the LEDs 101 to 104 at the photodetectors 106a to 106d, 107a to 107d, 108a to 108d, 109a to 109d in a predetermined state of the wrist 2 of the operator M (when a power of the palm is released to the most natural state, for example) is set as an index, and how the light-receiving signal distribution has been rotated by rotation of the ring body 105 around the wrist 2 is detected by checking with the light-receiving pattern table stored in the mounted position pattern memory 140.

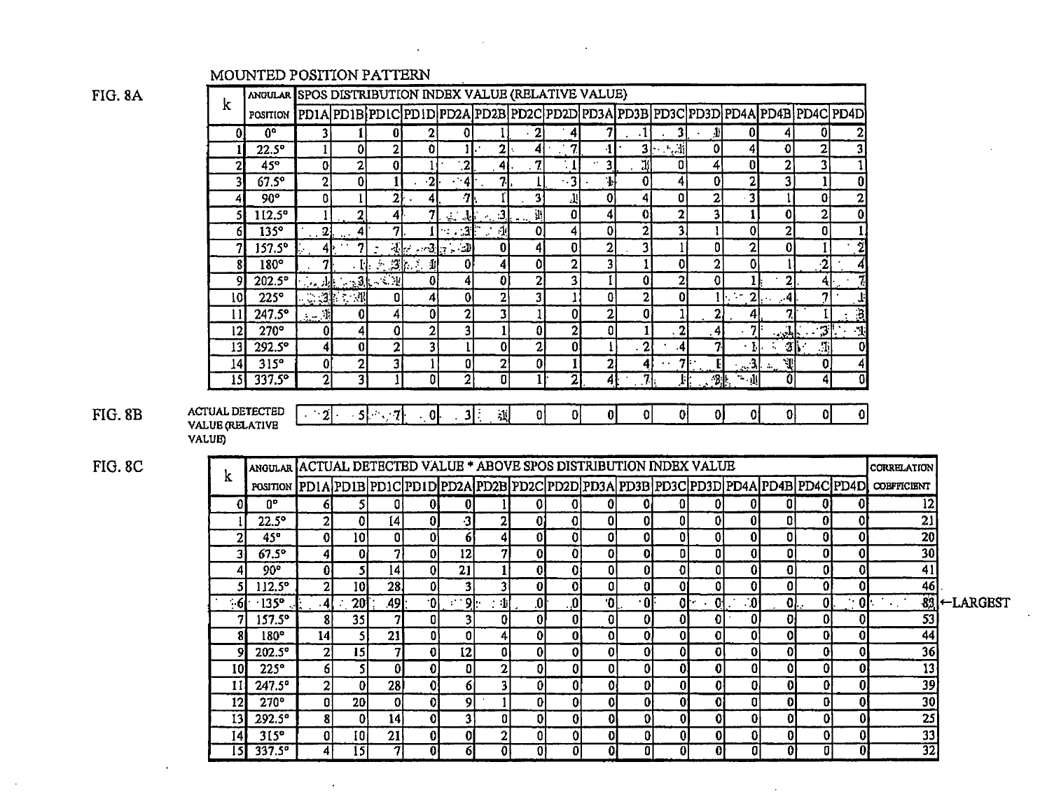

FIG. 8A is an explanatory diagram for explaining an example of the light-receiving pattern table and as mentioned above, the distribution of the light-receiving signal (light-receiving pattern) of irradiation light from any of the LEDs 101 to 104 at the photodetectors 106a to 106d (“PD1A”, “PD1B”, “PD1C”, “PD1D”), 107a to 107d (“FD2A”, “PD2B”, “PD2C”, “PD2D”), 108a to 108d (“PD3A”, “PD3B”, “PD3C”, “PD3D”), and 109a to 109d (“PD4A”, “PD4B”, “PD4C”, “PD4D”) in a predetermined state of the wrist 2 of the operator M (when a power of the palm is released to the most natural state, for example) is indicated as an index in relative values. As in the figure, the relative “3”, “1”, “0”, “4”, “0”, “2” in the order of the photodetectors 106a, 106b, 106c, 106d, 107a, 107b, 107c, 107d, 108a, 108b, 108c, 108d, 109a, 109b, 109c, 109d (at a reference position, which will be described later). The values “2”, “4”, “7”, “1”, “3”, “1” of the photodetectors 107c, 107d, 108a, 108b, 108c, 108d of the shaded portion in the figure indicate a range where the detected value can appear most easily as characteristics in the wrist 2, which is a detected portion (close to a blood vessel or muscle, for example).

Here, in this table, as shown on the uppermost row in FIG. 8A, a given state (when the wrist 2 is located on the front side and the LED 101 is opposed at the center part in the width direction of the wrist 2 when seen from the operator M, for example) is set as a reference position (θ=0°) in the rotating direction for the above distribution, and the light receiving pattern at this reference position (reference-position light-receiving pattern) is stored. And the detection control part 120 creates a pattern obtained by rotating the above light-receiving pattern for a predetermined angular interval (in this example, by 22.5° obtained by dividing the 360° range by 16) on the basis of the light-receiving pattern at this reference position (uppermost row in FIG. 8A) and temporarily stores it in an appropriate memory, not shown. Each row other than the uppermost one in FIG. 8A is shown in a list format for facilitation of understanding. Each value of k=0 to 15 is a variable for counting an offset position from the reference position, in which k=0 corresponds to the angular position θ=0° (reference position itself), k=1 corresponds to the angular position θ=22.5°, and the same applies to the following similarly to k=15 corresponding to the angular position θ=337.5°.

FIG. 5B shows an example of actual detected values to be checked with the light-receiving pattern at each offset position of k=0 to 15 prepared as in FIG. 8A and in this example, the values are “2”, “5”, “7”, “0”, “3”, “1”, “0”, “0”, “0”, “0”, “0”, “0”, “0”, “0”, “0”, “0” in the order of the photodetectors 106a, 106b, 106c, 106d, 107a, 107b, 107c, 107d, 108a, 108b, 108c, 108d, 109a, 109b, 109c, 109d.

FIG. 8C is a diagram for explaining a method of detecting a position in the rotating direction of the current ring body 105 finally by checking with the light-receiving pattern of each offset position shown in FIG. 8A in the case of the distribution of the light-receiving signals as in FIG. 8B. In this example, a product of each value (multiplied value) of an actual detected value (expressed in relative value) at each of the photodetectors 106a to 106d, 107a to 107d, 108a to 108d, 109a to 109d shown in FIG. 8B and each of the relative values displayed in each row in FIG. 8A is acquired. And for each row (in other words, for each angular position), the multiplied values acquired for the photodetectors 106a to 106d, 107a to 107d, 108a to 108d, 109a to 109d are totaled as correlation functions.

According to such method, among the index values of the light-receiving patterns calculated for the angular position (θ=0° to 337.5°) in each row as in FIG. 8A, the one closest to the angular position in the rotating direction when the actual detected value shown in FIG. 8B is obtained should have the largest correlation function, which is the total of the multiplied values. Therefore, suppose that the mounted position of the ring body 105 at this time is located at a position offset from the reference position by an angle substantially equal to the angular position (θ=135° in this example) where the largest value can be obtained, the mounted position (absolute position) can be detected. Not limited to the method of calculating such correlation function and calculating the mounted position on the basis of the pattern that obtains the largest value (or a value not less than a predetermined value), the mounted position may be acquired based on whether the index values (if the index values of the above light-receiving pattern can be made more simplified values, for example) match each other or not.

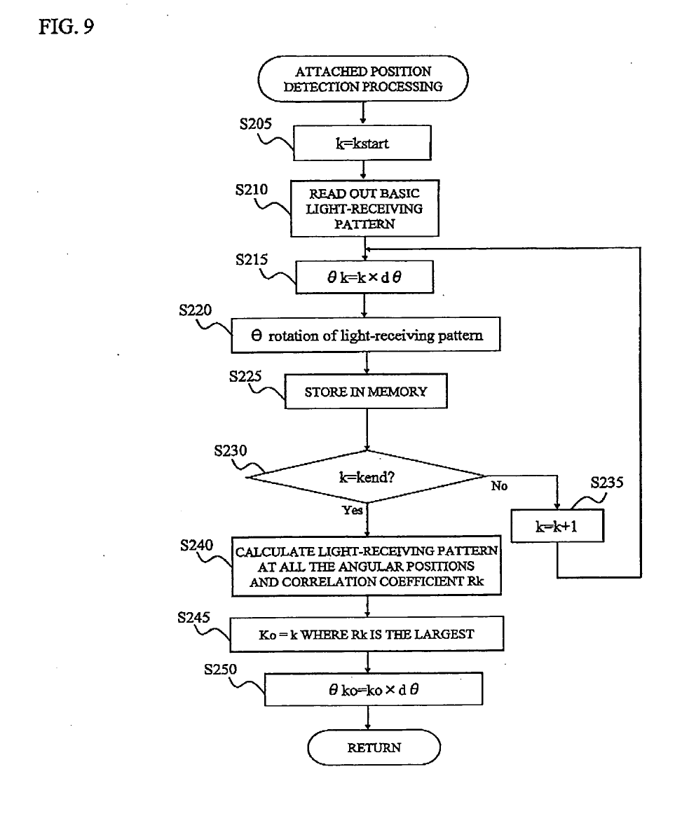

FIG. 9 is a flowchart illustrating a detailed procedure of Step S200 in order to realize the method principle.

First, at Step S205, a value of the above-mentioned offset position count variable k is set to its initial value kstart (0° in the example in FIG. 8A). The value of kstart may be set fixedly or may be operated (or selected) and inputted by the operator every time.

And at Step S205, a basic light-receiving pattern corresponding to the above kstart (0 in the example in FIG. 8A) is read out of the mounted position pattern memory 140 and temporarily stored in an appropriate memory.

Subsequently, the routine goes to Step S215, where using the above mentioned predetermined angular interval dB (22.50 in the example in FIG. 8A), an angular position θk=k×dB corresponding to each offset position variable k is defined.

And at Step S220, such distribution that the basic light-receiving pattern (corresponding to k=kstart) obtained at Step S210 and stored in the memory is rotated (offset) by the attached angle θk acquired at Step S215 is obtained and stored in the memory at Step S225.

Subsequently, at Step S230, it is determined if k has reached a predetermined rotation completed value kend (337.5° in the example in FIG. 8A) determined in advance. The value of the kend may be set fixedly or may be operated (or selected) and inputted by the operator each time. In the case of k<kend, the determination is not satisfied, 1 is added to k at Step S235, and the routine returns to Step S215, where the same procedure is repeated. By such repetition, the light-receiving pattern of each row other than the uppermost row is sequentially created from the basic light-receiving pattern (k=0°) on the uppermost row in FIG. 8A and stored in the memory.

If it becomes k=kend (337.5° in the example in FIG. 8A) is reached, the determination at Step S230 is satisfied, and the routine goes to Step S240.

At Step S240, as previously described in FIG. 8C, by multiplying distribution of all the light-receiving result signals Spos (may be a light-receiving signal of any of the LEDs 101 to 104 and may be either one of the first LED and the second LED) obtained by four-times repetition of Step S15 to Step S40 in FIG. 7 at this time by each value of each light-receiving pattern of k=kstart to end stored and accumulated in the memory at Step S225, a correlation coefficient Rk is calculated for each offset position variable k.

Subsequently, at Step S245, on the basis of the result at Step S240, the offset position variable k where the correlation function Rk is the largest is set as an offset position ko corresponding to the position of the current actual ring body 105.

And at Step S250, the mounted angle θko of the actual ring body 105 is calculated by θko=ko×dθ, using ko calculated at Step S245 and the above-mentioned dθ and this flow is finished.

FIG. 10 is a flowchart illustrating a detailed procedure of Step S300.

In FIG. 10, first, at Step S310, all the light-receiving result signals Spos (may be a light-receiving signal of any of the LEDs 101 to 104 and may be either one of the first LED and the second LED) obtained by four-times repetition of Step S15 to Step S40 in FIG. 7 at this time is rotated by the mounted angle θko of the ring body 105 calculated at the previous Step S200 for rotation position correction.

Subsequently, the routine goes to Step S315, where a light-receiving pattern corresponding to a start instruction operation (such as sticking out only the forefinger, for example) of the wrist 2 determined in advance as a cue (trigger signal) to start detection of the operation manipulation by the operator M and stored in the start pattern memory 150 is read out of the start pattern memory 150. And a correlation coefficient R between this read-out start pattern and the light-receiving pattern corrected at Step S310 is calculated similarly to the above-mentioned method.

And at Step S320, it is determined if the value of the correlation coefficient R calculated at Step S310 is larger than a predetermined value Rs set in advance, that can be considered as substantially equal with a considerable probability in view of pattern recognition. In the case of R>Rs, the determination is satisfied, and the routine goes to Step S330, where the flag G indicating recognition/unrecognition of the instruction is set to 1 (recognized). In the case of R≦Rs, the determination is not satisfied, and the routine goes to Step S325, where the flag G is set to 0 (unrecognized). When Step S330 or Step S325 is completed, this flow is finished.

FIG. 11 is a flowchart illustrating a detailed procedure of Step S400.

In FIG. 11, first, at Step S410, all the light-receiving result signals Spos (may be a light-receiving signal of any of the LEDs 101 to 104 and may be either one of the first LED and the second LED) obtained by four-times repetition of Step S15 to Step S40 in FIG. 7 at this time is rotated by the mounted angle θko of the ring body 105 calculated at the previous Step S200 for rotation position correction.

Subsequently, the routine goes to Step S415, where a light-receiving pattern corresponding to a stop instruction operation (such as sticking out only the little finger, for example) of the wrist 2 determined in advance as a cue (trigger signal) to stop detection of the operation manipulation by the operator M and stored in the stop pattern memory 160 is read out of the stop pattern memory 160. And a correlation coefficient R between this read-out stop pattern and the light-receiving pattern corrected at Step S410 is calculated similarly to the above-mentioned method.

And at Step S420, it is determined if the value of the correlation coefficient R calculated at Step S410 is larger than a predetermined value Re set in advance, that can be considered as substantially equal with a considerable probability in view of pattern recognition. In the case of R≧Re, the determination is satisfied, and the routine goes to Step S430, where the flag G indicating recognition/unrecognition of the instruction is set to 1 (recognized). In the case of R≦Re, the determination is not satisfied, and the routine goes to Step S425, where the flag G is set to 0 (unrecognized). When Step S430 or Step S425 is completed, this flow is finished.

FIG. 12 is a functional block diagram illustrating functional configuration of the above-mentioned controller 200.

In FIG. 12, the controller 200 comprises an input signal creation control part 210, a light-receiving pattern memory 220 that stores and holds a light-receiving pattern (=reference attitude light-receiving pattern) set in advance as living body information distribution such as a blood vessel, muscle and the like corresponding to attitudes of an operation portion (finger and the like) of the operator M in each operation mode, a light-receiving pattern analysis portion 230 that analyzes an operation mode (intension) of the operator (details will be described later), a learning processing portion 231 provided at the light-receiving pattern analysis portion 230 (details will be described later), a radio communication control part 240 provided with a known antenna, a communication circuit and the like and configured to carry out radio communication with the operating apparatus 100, and an external input/output interface (I/F) 250 similarly provided with a known antenna, a communication circuit and the like and configured to carry out radio communication with an external device other than the operating apparatus 100 (the display device 300 in this example) and a battery BT for power supply.

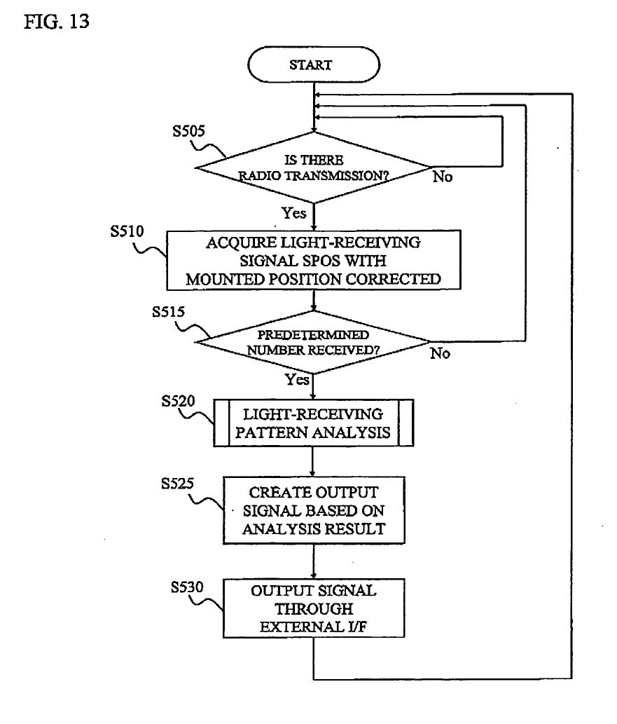

FIG. 13 is a flowchart illustrating an example of a control procedure executed by the entire controller 200. In FIG. 13, first, at Step S505, it is determined at the input signal creation control part 210 if radio signal data has been transmitted from the radio communication control part 190 provided at the operating apparatus 100 through the radio communication control part 240 or not. If there has been data transmission, the determination is satisfied, and the routine goes to Step S510.

At Step S510, at the input signal creation control part 210, a light-receiving correction signal obtained by four-times repetition of the above-mentioned Step S15 to Step S40 after the operation start instruction and before the operation stop instruction, corresponding to the operation intention of the operator M (=SposiA and SposiB) and moreover, applied with mounted angle θko correction is extracted and obtained from radio signal data from the operating apparatus 100 received at Step S505 and stored and accumulated in an appropriate memory.

Subsequently, the routine goes to Step S515, where it is determined at the input signal creation control part 210 if the data obtained at Step S510 has been accumulated to a predetermined number (number of attitudes of the hand enough to constitute a single operation mode by the hand of the operator M, for example) or not. If the number of accumulated data is less than the predetermined number, the determination is not satisfied, and the routine returns to Step S505, where the same procedure is repeated. If the accumulated data has reached the predetermined number, the determination at Step S515 is satisfied and the routine goes to Step S520.

At Step S520, at the light-receiving pattern analysis portion 230, referring to the light-receiving pattern (reference attitude light-receiving pattern) stored in the light-receiving pattern memory 220 in order to specify the attitude of the hand of the operator, the attitude of the hand of the operator M (any of “stone”, “paper”, “scissors” and the like, for example) is analyzed by comparing the reference attitude light-receiving pattern and the light-receiving pattern on the basis of the operation signal inputted from the operating apparatus 100. Moreover, using a plurality of analysis results on the attitude of the hand of the operator M, based on the continuity, the operation mode of the operator M (operation intention “stone->scissors->paper” and the like) is analyzed.

Subsequently, the routine goes to Step S525, where at the input signal creation control part 210, on the basis of the operation mode of the operator M analyzed at Step S520, a corresponding operation signal (“open file”, “display next page” and the like, for example) is created.

And at Step S530, at the external input/output interface 250, the operation signal created at Step S525 is outputted to the display device 300 (head-mount display) via radio communication, and the routine returns to Step S505, where the same procedure is repeated.

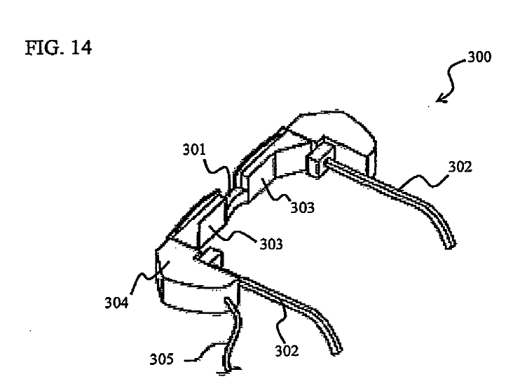

FIG. 14 is a perspective view illustrating a detailed appearance structure of the display device 300. In FIG. 14, the display device 300 has a nose holding portion 301 mounted and held on the nose 6 of the operator M, an ear holding portion 302 mounted and held on both ears 5 of the operator M, respectively, a display portion 303 located in front of the both eyes of the operator M at mounting and showing predetermined display, a support portion 304 that supports the display portions 303, and a control part (not shown) connected to the display portion 303 through a cable 305.

The control part receives the operation signal from the controller 200 via radio communication and on the basis of this operation signal, a control signal to the two display portions 303 is created and outputted through the cable 305 and has corresponding display made on the display portions 303.

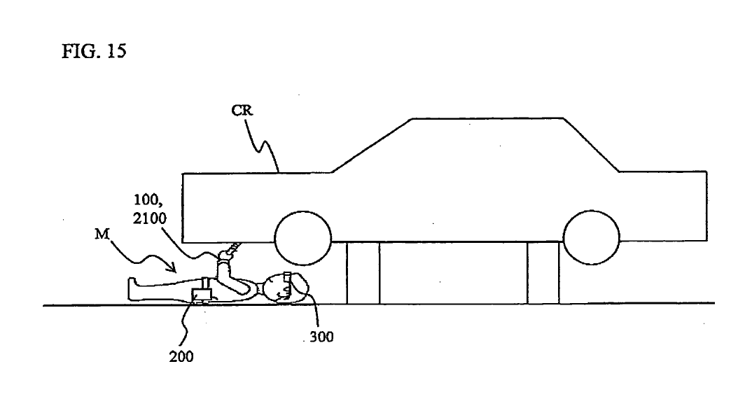

FIG. 15 is an explanatory diagram illustrating an example in which the above operating system is actually utilized. In FIG. 15, the operator M in this example is servicing an automobile CR and working with an appropriate tool in hand in a state lying down and sliding under the floor of the jacked-up automobile CR as shown. At this time, by display control of the controller 200 (detailed explanation is omitted), a display control signal of a service manual is transmitted to the control part of the display device 300 via radio communication, by which the service manual is displayed on the display portion of the display device 300 (so that the operator M can visibly recognize it with the both eyes). And at this time, when the operator M operates the finger or hand as appropriate (such as the above-mentioned “stone”, “scissors”, “paper” and the like), the light-receiving pattern corresponding to the operation mode is transmitted from the operating apparatus 100 to the controller 200, and the intention to turn the page of the service manual by the operator is analyzed on the basis of the operation mode at the light-receiving pattern analysis portion 230 of the controller 200 so that the corresponding page transmission processing can be executed. Thereby, the operator M can perform the optimal automobile servicing work by referring to a desired page on the service manual with the tool in his hand without bringing the manual as a paper publication under the floor or turning a page.

In the above, Step S15 to Step S40 of the flow executed by the detection control part 120 shown in FIG. 7 constitute a pattern detecting portion configured to detect a light emitting device and at least one light-receiving device that received irradiation light from the light emitting device as the light-receiving pattern described in each claim. Further, Step S95 and the radio communication control part 190 constitute a signal output device configured to output an operation signal corresponding to the operation state of the operator on the basis of the light-receiving pattern detected by the pattern detecting portion. Moreover, Step S90 constitutes a correcting portion configured to correct the light-receiving pattern detected by the pattern detecting portion corresponding to a position detection result of the position detecting device.

Step S300 and Step S70 in the flow in FIG. 7 constitute a start instruction determining portion configured to determine if a start instruction to start output of the operation signal by the signal outputting device has been inputted or not, and Step S315, Step S320 in the flow in FIG. 10 constitute a comparing portion for start instruction detection configured to compare the light-receiving pattern detected by the pattern detecting portion and a light-receiving pattern for start instruction determined in advance.

Step S400 and Step S80 in the flow in FIG. 7 constitute a stop instruction determining portion configured to determine if a stop instruction to stop output of the operation signal by the signal outputting device has been inputted or not, and Step S415, Step S420 in the flow in FIG. 11 constitute a comparing portion for stop instruction detection configured to compare the light-receiving pattern detected by the pattern detecting portion and a light-receiving pattern for stop instruction set in advance.

Step S240 in the flow in FIG. 9 constitutes a comparing portion for position detection configured to compare the light-receiving pattern detected by the pattern detecting portion and the reference position light-receiving pattern set in advance, and Step S250 constitutes a position detecting portion configured to detect a position in a rotating direction of the operating apparatus on the basis of the comparison result by the comparing portion for position detection.

Step S525 in the flow of FIG. 13 executed by the input signal creation control part 210 of the controller 200 constitutes an attitude calculation portion that calculates an attitude of the operation portion of the operator or a change mode of the attitude on the basis of the light-receiving pattern obtained from the operation signal inputted from the signal outputting device. Further, Step S520 constitutes a comparing portion for calculation that compares the reference attitude light-receiving pattern set according to a living body information distribution corresponding to a predetermined attitude of the operation portion of the operator and the obtained light-receiving pattern.

In the operating system of this embodiment configured as above, when the operator M mounts the operating apparatus 100 on the wrist 2 through the ring body 5 and the wrist 2 is moved by some operation of the finger or hand in the mounted state, the irradiation light emitted from the LEDs 101 to 104 creates a transmission light or scattering light pattern corresponding to the state of the wrist 2 on the basis of the attitude of the finger or hand or a change in the attitude, and the light is received at the photodetectors 106a to 106d, 107a to 107d, 108a to 108d, 109a to 109d at the respective corresponding positions. As above, since various light-receiving results are generated at the plurality of photodetectors 106a to 106d, 107a to 107d, 108a to 110d, 109a to 109d corresponding to the movement of the wrist 2 of the operator M, on the basis of the combination of the light-receiving results, an operation signal corresponding to the operation state of the finger or hand of the operator M can be outputted.

As mentioned above, by detecting the attitude of the finger or hand and the like of the operator M through an optical method and outputting an operation signal, an operation reflecting the intension of the operator with high accuracy can be realized. Further, since a non-contact optical method is used, there is no need to bring an electrode and the like into close contact with the body of the operator M as in a method by musclepotential or acceleration detection, and comfortable operation can be carried out without giving a sense of pressure or discomfort to the operator M.

Particularly in this embodiment, the change in distribution of the living body information such as blood vessel distribution/muscle distribution/skin surface shape and the like of the wrist 2, which is changed when the operator M changes the attitude of the finger or hand is detected as a change in a behavior of transmission light or scattering light of the irradiation light of the LEDs 101 to 104, that is, a change in the light-receiving pattern of the photodetectors 106a to 106d, 107a to 107d, 108a to 108d, 109a to 109d. Specifically, the light-receiving pattern obtained in advance at a predetermined reference attitude is held in the light-receiving pattern memory 220 of the controller 200 as the reference attitude light-receiving pattern, and the reference attitude light-receiving pattern and the light-receiving pattern currently transmitted after being detected at the operating apparatus 100 and applied with rotation-position correction are compared at the controller 200. On the basis of this comparison, a difference between the current light-receiving pattern and the light-receiving pattern at the reference attitude is known, and the attitude of the finger or hand of the operator M or the change mode of the attitude can be calculated in a form according to the difference.

Further, particularly in this embodiment, since the LEDs 101 to 104 and the photodetectors 106a to 106d, 107a to 107d, 108a to 108d, 109a to 109d are arranged substantially annularly on the ring body 105, they can be made in a structure that can be easily attached to the wrist as mentioned above or any other parts such as torso, neck, ankle, arm and head of the operator M.

In addition, since the LED 101 and the photodetectors 106a to 106d, the LED 102 and the photodetectors 107a to 107d, the LED 103 and the photodetectors 108a to 108d, and the LED 104 and the 109a to 109d are arranged so that each group is in rotation symmetry to each other, even if the operating apparatus 100 is rotated and offset in the mounted state to the body (the wrist 2 in this example) of the operator M through the ring body 105, the light-receiving pattern can be detected without trouble. As a result, on the presumption that the rotating offset is allowed, a gap between the operating apparatus 100 and the body of the operator M in the ring body 105 can be taken large, which can prevent the sense of pressure or discomfort to the operator M more securely.

Further, particularly in this embodiment, by correcting an offset by the correcting portion in correspondence with a detection result indicating how far the current light-receiving pattern is offset in the rotating direction with respect to the reference position light-receiving pattern, the operating apparatus 100 can output an operation signal in a form reflecting the correction. Therefore, since the operation signal determined only by the reference attitude can be outputted regardless of the offset in the rotating direction, there is no more need for the operator M to worry about the rotating offset after the operating apparatus 100 is mounted through the ring body 105, by which comfort can be further improved.

Further, particularly in this embodiment, not by outputting a signal all the time from the operating apparatus 100 but by outputting a signal when a predetermined start instruction is made, a wasteful operation of the operating apparatus 100 such as output of a detection signal at non-operation time not intended by the operator can be eliminated and power consumption can be saved. At this time, as a specific start instruction, a light-receiving pattern obtained in advance at a predetermined start instruction attitude is held in the start pattern memory 150 of the operating apparatus 100 as a light-receiving pattern for start instruction, the light-receiving pattern for start instruction and the light-receiving pattern currently detected by the operating apparatus 100 are compared and determination is made on whether the start instruction has been inputted or not on the basis of the comparison. As a result, if the operator M wants to start output of the operation signal by the operating apparatus 100, it is only necessary to take the above predetermined start instruction attitude and no other special operation is required. As a result, wasteful power consumption can be prevented without increasing an operation labor.

Further, particularly in this embodiment, by stopping signal output when a predetermined stop instruction is made after the signal output from the operating apparatus 100 is started, a wasteful operation of the operating apparatus 100 such as output of a detection signal at non-operation time not intended by the operator M can be eliminated and power consumption can be saved. At this time, as a specific stop instruction, the light-receiving pattern obtained in advance at a predetermined stop instruction attitude is held in the stop pattern memory 160 of the operating apparatus 100 as a light-receiving pattern for stop instruction, the light-receiving pattern for stop instruction is compared with the light-receiving pattern currently detected by the operating apparatus 100, and on the basis of the comparison, it is determined if the stop instruction has been inputted or not. As a result, if the operator M wants to stop output of the operation signal by the operating apparatus 100, it is only necessary to take the above predetermined stop instruction attitude and any other special operation is not required. As a result, the wasteful power consumption can be prevented without increasing an operation labor.

This embodiment is not limited to the above mode but various variations are possible in a range not departing from its gist and technical idea. The variations will be described below.

(1-1) When Light is Emitted at the Same Time Using Filter Device:

In the above embodiment, the LEDs 101 to 104 are sequentially emitted (with a predetermined time difference) but not limited to that, they may be emitted at the same time and they may be separated on the light-receiving side to each predetermined wavelength band using a filter device.

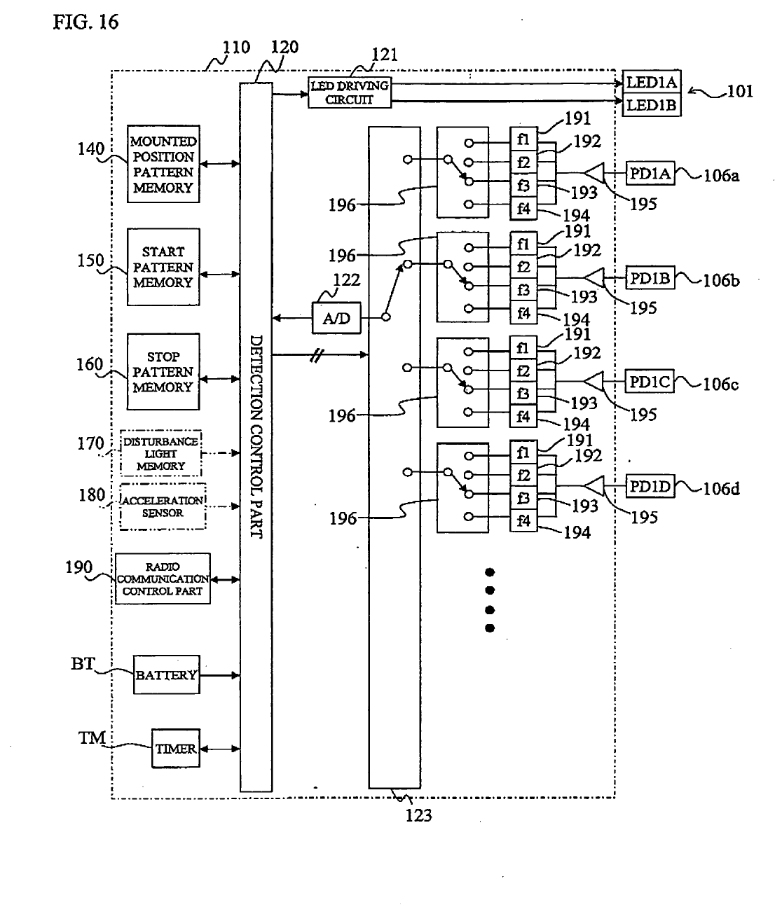

FIG. 16 shows one of such variations (in order to prevent complexity of the figure, a part thereof is omitted in the illustration). In this example, the LEDs 101, 102, 103, 104 are modulated by the above corresponding LED driving circuits 121, 124, 127, 130 with modulation frequencies f1, f2, f3, f4 different from each other for irradiation. And in response to that, an amplifier 195 that amplifies a signal received at each of the photodetectors 106a to 106d, 107a to 107d, 108a to 108d, 109a to 109d, electric filters 191, 192, 193, 194 (filter devices) to which the signal amplified by the amplifier 195 is inputted and which extracts and separates them according to the above modulation frequencies f1, f2, f3, f4, and a switch 196 configured to selectively input outputs from the filters 191, 192, 193, 194 to any of the switches 123, 126, 129, 132 are provided.

In this case, the irradiation light emitted from the LEDs 101 to 104, which are applied with simultaneous light-emission control (=simultaneous light-emission control portion), and received at the photodetectors 106a to 106d, 107a to 107d, 108a to 108d, 109a to 109d at the same time is separated to each of the predetermined modulation frequency bands (modulation frequencies f1, f2, f3, f4 in this example) at each of the filters 191, 192, 193, 194 and then, inputted to the detection control part 120 through the switch 196 and the switches 123, 126, 129, 132 so that separate detection processing can be executed for each irradiation light of each of the LEDs 101 to 104. And by receiving the light emitted at the same time without carrying out the light emission with a time difference, time required for light emission and light receiving can be reduced and efficient detection can be made as compared with the sequential light emission as in the above embodiment.

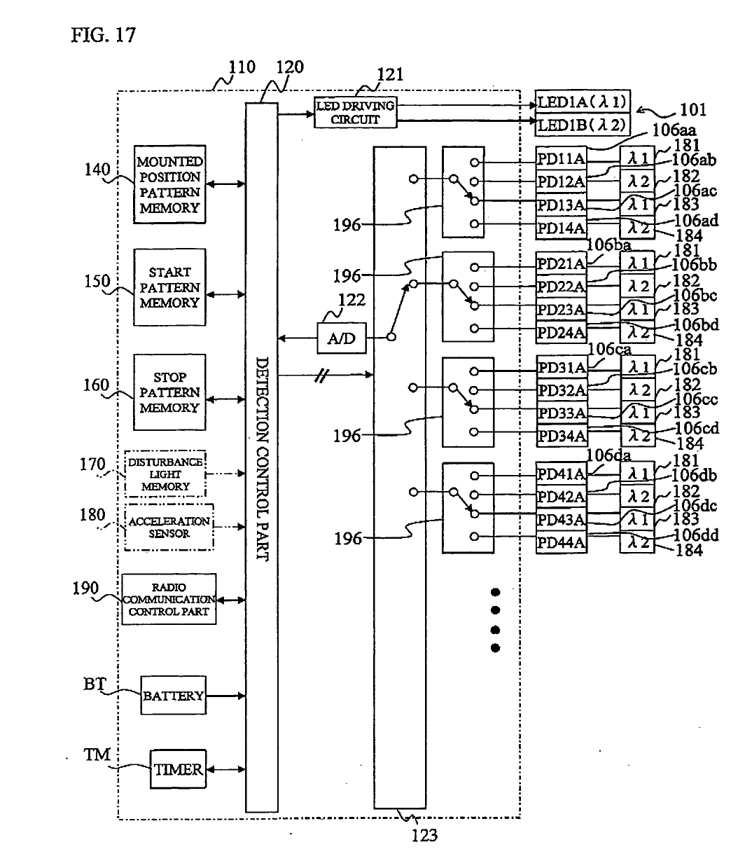

FIG. 17 illustrates another variation using the filter device (in order to prevent complexity of the figure, a part thereof is omitted in the illustration). Similarly to the above, the LEDs 101, 102, 103, 104 irradiate wavelengths λ1, λ2, which are different from each other, corresponding to LED1A, LED1B. In correspondence with that, the photodetectors 106a to 106d, 107a to 107d, 108a to 108d, 109a to 109d are provided in the number corresponding to the above wavelengths λ1, λ2 (two in this example) each (for the photodetector 106a, for example, the photodetectors 106aa, 106ac corresponding to the wavelength λ1 and the photodetectors 106ab, 106ad corresponding to the wavelength λ2). Moreover, as a filter device configured to extract and separate the received light component by the above wavelength and supply to those four photodetectors, a physical spectral filter (λ1) 181, a spectral filter (λ2) 182, a spectral filter (λ1) 183, a spectral filter (X2) 184 are provided. As an example of such spectral filter, infrared transmission filter, red, green, blue visible transmission filters and the like can be used, for example.

In this case, the irradiation light emitted from the LED101a, 101b, which are applied with simultaneous light-emission control (=simultaneous light-emission control portion), is separated at the same time by predetermined wavelength band (wavelengths λ1, λ2, in this example) at each filter 181, 182, 183, 184 and received and then, supplied to the photodetectors 106aa, 106ab, 106ac, 106ad, the photodetectors 106ba, 106bb, 106bc, 106bd, . . . 109da, 109db, 109dc, 109dd and moreover inputted to the detection control part 120 through the switch 196 and the switches 123, 126, 129, 132 so that separate detection processing can be executed for each irradiation light of each of the LEDs 101a, 101b And by receiving the light emitted at the same time without carrying out the light emission with a time difference by light-emission wavelength, time required for light emission and light receiving can be reduced and efficient detection can be made as compared with the sequential light emission as in the above embodiment.

(1-2) When Neural Network Method is Used:

In the above embodiment, at position correction in the rotating direction of the ring body 105, matching/non-matching between the detected light-receiving pattern and the reference position light-receiving pattern is checked or similarity between those two light-receiving patterns are quantified by a predetermined function and a value not less than a predetermined one is selected at the correction, but not limited to that. That is, using a method of neural network using weighted repeat calculation, how much the current light-receiving pattern is offset in the rotating direction may be detected, for example.

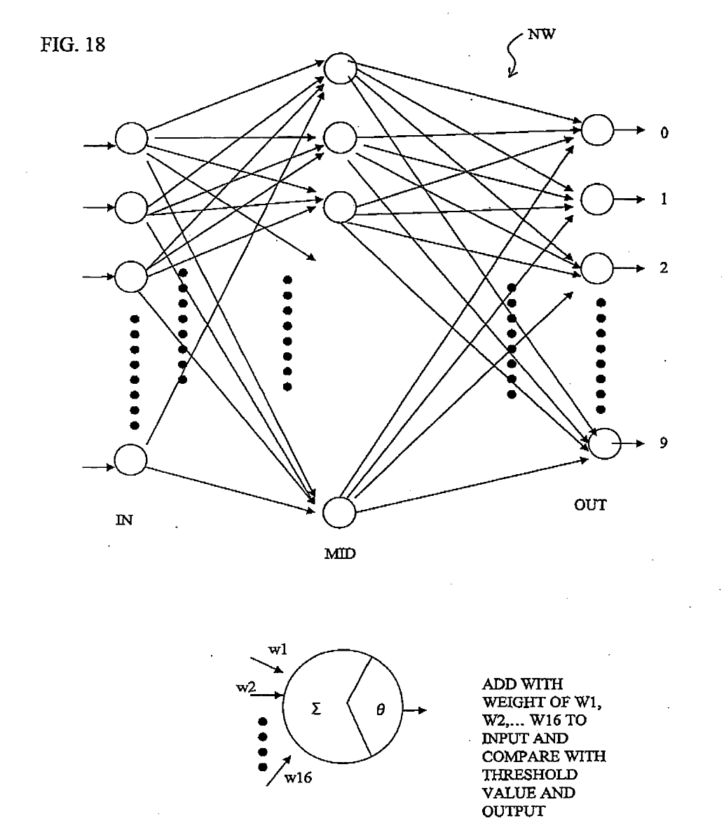

FIG. 18 is a conceptual explanatory diagram for illustrating a method and principle of the neural network. The neural network is a method in which a system is made to learn so that a right solution is presented to various inputs by presenting a right solution (teacher signal) of output and changing connected weights. In FIG. 18, by making numerical input, numerical calculation is carried out at an input layer INT, a middle layer MID, an output layer OUT, and numerical outputs are made. If a right solution (teacher signal) of the output to the input is known, by telling this teacher signal and by changing a value of the connected weight of a unit at each layer little by little, an error between the numerical output to the various inputs and the teacher signal can be minimized (made to learn).

That is, supposing that the output of the network is o, and the teacher signal is y, a loss function R can be expressed as follows with an index of the unit in the output layer OUT as j:

R=Σⱼ(oⱼ−yⱼ)²

Here, the learning of the neural network by this network NW is achieved by modifying the connected weight as above, and a modification amount w of the connected weight of the middle layer MID and the output layer OUT can be expressed as follows using the above loss function R:

ΔWᵢⱼ=−ε(∂R/∂wᵢⱼ)

(where i: index of the middle layer MID, ε: learning coefficient).

Moreover, the modification amount of the connected weight of the input layer INT and the middle layer MID can be calculated using the modification amount of the connected weight of the middle layer MID and the output layer OUT (an error of the network is propagated from the rear layer to the front layer, by which the entire network is made to learn).

In order to realize the neural network method as above, it is only necessary that the detection controller 110 is provided with a learning mode that obtains parameters required for determination on the basis of the teacher signal and a determination mode that makes determination from the parameters and the obtained data, and a determination comparing portion having a memory portion in which the parameters are stored (may be the one corresponding to the learning processing portion 231 provided at the light-receiving pattern analysis portion 230 of the controller 200, which will be described later, for example) is also provided. The determination comparing portion obtains parameters on the basis of the teacher signal in the learning mode, the determination is made in the determination mode by the parameters and the obtained data and by repeating this, the reference position light-receiving pattern and the light-receiving pattern detected by the pattern detecting portion can be compared by the so-called neural network method.

(1-3) When Disturbance is to be Removed:

That is, it may be so configured that the light-receiving results at the photodetectors 106a to 106d, 107a to 107d, 108a to 108d, 109a to 109d, when the LEDs 101 to 104 do not emit light (by external light), are considered as a disturbance component and stored in a disturbance light memory 170 (See FIG. 6 and the like) provided at the detection controller 110, the disturbance component of the disturbance light memory 170 is subtracted from the light-receiving results at the photodetectors 106a to 106d, 107a to 107d, 108a to 108d, 109a to 109d when the LEDs 101 to 104 emit light, and the light-receiving pattern is obtained from a differential signal. As a result, such an effect is realized that an influence of the light-receiving value by the external light to be disturbance at detection is removed and detection with higher accuracy can be carried out.

(1-4) When Attitude Analysis is Also Conducted on the Operating Apparatus 100 Side:

In the above, on the operating apparatus 100 side, only the detection of the operation start instruction and operation stop instruction and rotating position correction of the light-receiving signal are performed, and the attitude analysis of the finger and hand of the operator M on the basis of the light-receiving signal reflecting the behavior of the transmission scattering light or reflection scattering light at the wrist 2 corresponding to the operation intension of the operator M is carried out on the controller 200 side. However, such attitude analysis function and others may be carried out by the operating apparatus 100, not on the controller 200 side.

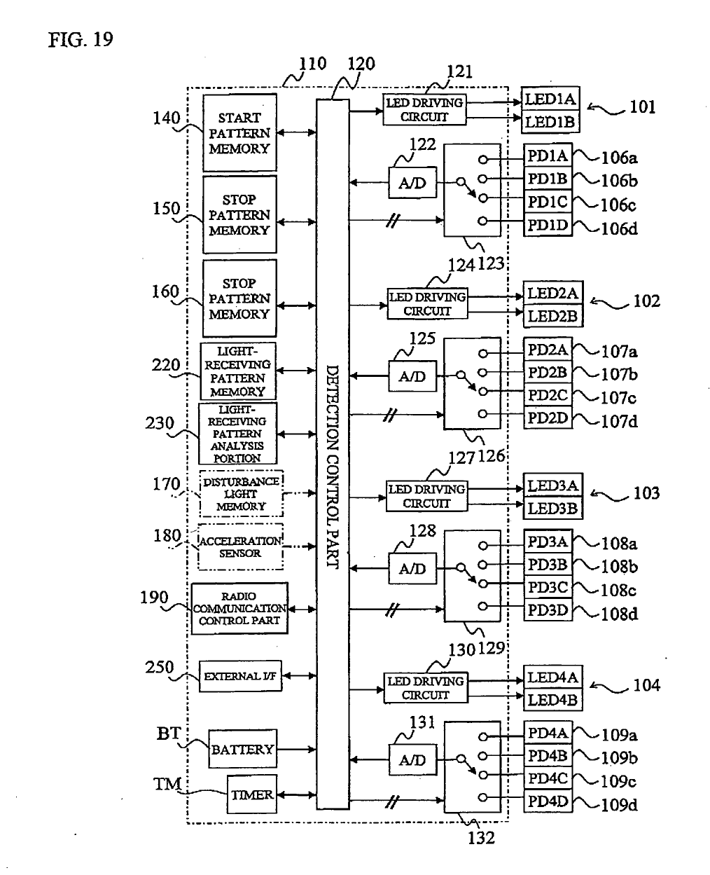

FIG. 19 is a functional block diagram illustrating a control system in this variation and corresponds to the above-mentioned FIG. 6 and FIG. 12. The same reference numerals are given to portions equivalent to those in FIG. 6 and FIG. 12 and explanation will be omitted or simplified as appropriate. In the detection controller 110 shown in FIG. 19, the light-receiving pattern memory 220 in which the reference attitude light-receiving pattern corresponding to the attitude of the operation portion (finger, hand and the like) of the operator M in each operation mode is stored and held, the light-receiving pattern analysis portion 230 (learning processing portion 231 is not shown) that analyzes the operation mode (intension) of the operator, and the external input/output interface (I/F) 250 for radio communication with external equipment (display device 300 and the like) other than the operating apparatus 100 are provided on the side of the controller 200 in the above embodiment.

In this variation, the detection control part 120 of the detection controller 110 also performing a function of the input signal creation control part 210 of the controller 200 and other portions execute the control procedure similar to the flow chart shown in FIG. 13. That is, in the procedure equivalent to Step S505 (hereinafter referred to simply as Step S505), it is determined if the light-receiving signal data has been inputted (or accumulated) at the detection control part 120. If there has been data input or accumulation, the determination is satisfied and at Step S510, at the detection control part 120, the light-receiving correction signal corresponding to the operation intention of the operator M obtained by the above-mentioned four-times repetition of Step S15 to Step S40 after the operation start instruction and before the operation stop instruction (=SposiA and SposiB) and further applied with the mounted angle θko correction is extracted and obtained from the signal data identified at Step S505 and stored and accumulated in an appropriate memory.

Subsequently, the routine goes to Step S515, where at the detection control part 120, it is determined if the data obtained at Step S510 has been accumulated in the predetermined number (the number of attitudes of the hand sufficient to constitute a single operation mode by the hand of the operator M, for example) or not, and if the accumulated data has reached the predetermined number, the routine goes to Step S520, where at the light-receiving pattern analysis portion 230, referring to the light-receiving pattern (reference attitude light-receiving pattern) stored in the light-receiving pattern memory 220 for identification of the attitude of the hand of the operator, by comparing the reference attitude light-receiving pattern and the light-receiving pattern on the basis of the above accumulated operation signal, the attitude of the hand of the operator M (any of “stone”, “paper”, “scissors” and the like, for example) is analyzed. Moreover, using the plurality of analysis results of the attitude of the hand of the operator M, the operation mode of the operator M (operation intention “stone->scissors->paper” and the like) is analyzed on the basis of the continuity.

Subsequently, the routine goes to Step S525, where at the detection control part 120, on the basis of the operation mode of the operator M analyzed at Step S520, a corresponding operation signal (“open file”, “display next page” and the like, for example) is created and at Step S530, by the external input/output interface 250, the operation signal created at Step S525 is outputted via radio communication to the display device 300 (head-mount display), and the routine returns to Step S505 and the similar procedure is repeated.

In the above, Step S525 in the flow of FIG. 13 executed by the detection control part 120 constitutes a first attitude calculating portion that calculates the attitude of the operation portion of the operator or a change mode of the attitude on the basis of the light-receiving pattern corrected by the correcting portion. Further, Step S520 constitutes a first comparing portion for attitude detection that compares the reference attitude light-receiving pattern set according to the living body information distribution corresponding to the predetermined reference attitude of the operation portion of the operator and the light-receiving pattern corrected by the correcting portion.

In this variation, too, the same effect as the above embodiment is obtained. Further, by providing the function of the controller 200 at the operating apparatus 100 side, the controller 200 is not needed any more, which can reduce mounting burden and operation labor of the operator M.

(1-5) Others:

(1-5-1) When Acceleration Sensor is Used:

In the above, in the operation start instruction detection processing at Step S300 whose details are shown in FIG. 7 and the operation stop detection processing at Step S400, the start instruction and stop instruction was made by changing the attitude of the finger or hand of the operator M so as to be matched with the predetermined light-receiving pattern for start instruction and the light-receiving pattern for stop instruction, but not limited to that. That is, instead of the start instruction/stop instruction through such optical detection, by providing an acceleration sensor 180 at the ring body 105 (See FIGS. 3, 4, 6 and the like), and the start instruction/stop instruction may be given by applying an acceleration not less than a predetermined value by strongly shaking wrist 2 of the operator M and the like, for example. Moreover, the start instruction and stop instruction may be given by a usual operation switch and the like provided at the ring body 105 or other locations. In these cases, too, such an effect can be obtained that comfortable operation can be performed without giving a sense of pressure or discomfort to the operator M.

(1-5-2) Handling Personal Habits and the Like of Operator:

In the recognition and the like of the light-receiving pattern mentioned above, a function to have personal habits of the operator M, operation frequency of the specific operation portion and the like learned may be provided. For example, as shown in FIG. 12 by a imaginary line, a database 260 that stores personal habits, operation frequency information specific to the individual and the like is provided in the controller 200, and specific operation or operation mode is stored in the database 260 at a predetermined frequency by the learning processing portion 231 provided at the light-receiving pattern analysis portion 230 (or may be initially set for each operator M or in general). And when the operation portion (finger, hand and the like) of the operator M is analyzed on the basis of the light-receiving pattern at the light-receiving pattern analysis portion 230, the information in the database 260 may be referred to in the analysis.

(1-5-3) Application to Other Service Usages:

In the above, application of the present invention to reference to a service manual during servicing of an automobile has been explained as an example, but the present invention may be applied to input operation and the like to other inspection records. In addition, the present invention is not limited to the service related operations as above but can be applied generally to reception/guidance operations at offices, shops and other buildings and various meetings and the like (arrangement of a meeting room, check of appointment, various inputs on projector screen and large-sized display, operation and the like) and other service businesses in which an operator refers to a manual, documents and the like or uses electronic files. In this case, not only the page turning operation as above, all the operations carried out on usual operation equipment, personal computers and the like (file operation, editing operation, display operation and the like) can be performed using the corresponding light-receiving patterns. In addition, numeral/character input (including multi-tap input operation) and the like can be used instead of keyboard operation on a personal computer or mobile equipment (e-mail can be also transmitted/received). Moreover, application to game equipment (game machine and the like), game facilities (virtual sports facilities and the like) and other entertainment can obtain the same effect.

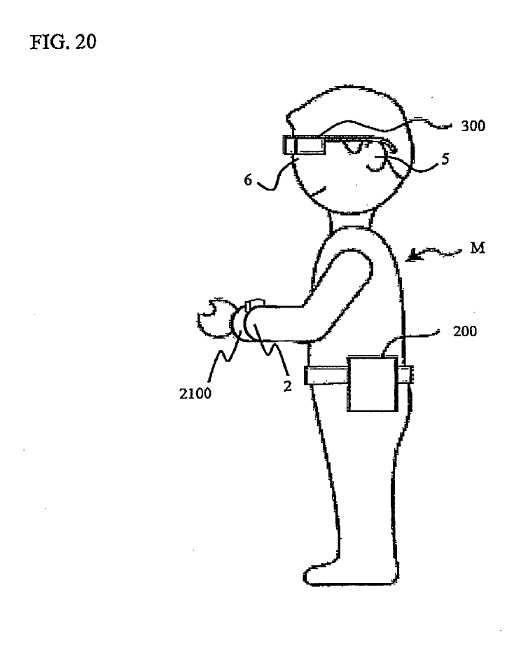

A second embodiment of the present invention will be described referring to FIGS. 20 to 33. This embodiment is an embodiment in which light is irradiated from the side of the back of the hand of the operator. The same reference numerals are given to portions equivalent to those in the first embodiment, and explanation will be omitted or simplified as appropriate.

FIG. 20 is an explanatory diagram for illustrating entire configuration of an operating system including the operating apparatus according to the embodiment and corresponds to FIG. 1 in the first embodiment.

As shown in FIG. 20, in this embodiment, an operating apparatus 2100 is used by being mounted on the wrist 2 (predetermined mounted position in the body) of the operator M.

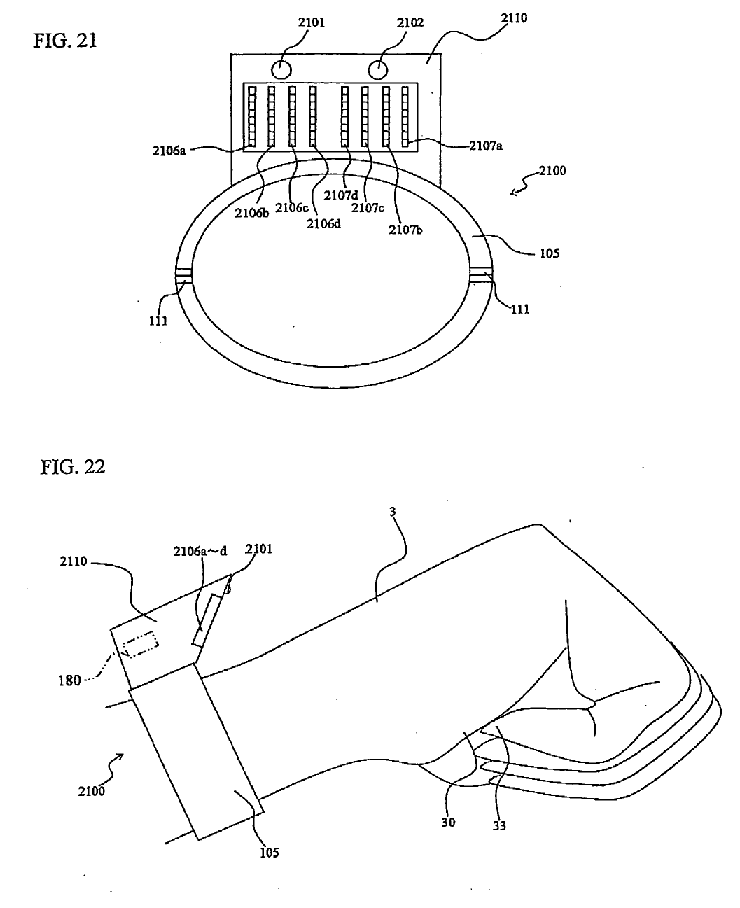

FIG. 21 is a front view illustrating a detailed structure of the operating apparatus 2100 and FIG. 22 is a view illustrating a state where the operating apparatus 2100 is mounted on the wrist 2 of the operator M.

In FIGS. 21 and 22, the operating apparatus 2100 has a substantially annular shape and a belt body 105 (mounting device) similar to the first embodiment to be mounted on the wrist 2 of the operator 2. At the belt body 105, at least one (two in this example) LEDs (light-emitting devices) 2101, 2102 emitting predetermined irradiation light, corresponding to the LEDs 101, 102, 103, 104 in the first embodiment, and at least one pair (two pairs in this example) photodetectors (light-receiving devices. Such as photodiode, phototransistor, CCD, CMOS sensor and the like, for example) 2106a to 2106d, 2107a to 2107d, corresponding to the photodetectors 106a to 106d, 107a to 107d, 108a to 108d, 109a to 109d of the above first embodiment, are provided.

Moreover, in the belt body 105, a detection controller 2110 that controls the LEDs 2101, 2102 and the photodetectors 2106 to 2107 and carries out predetermined detection processing (details will be described later), constituted by a calculating device such as a CPU and the like, for example, corresponding to the detection controller 110 in the first embodiment is provided.

For the irradiation light from the LEDs 2101, 2102 and its light-emitting behavior, those similar to the LEDs 101, 102, 103, 104 of the above first embodiment are enough, and the explanation will be omitted. And by emitting irradiation light in the near infrared light band from the LEDs 2101, 2102, change in scattering and change in blood flow distribution in a tissue of the operation portion (finger or palm, for example) involved in the operation of the operator M can be detected by the light-receiving behavior of the near infrared light at the photodetectors 2106a to 2106d, 2107a to 2107d.

In the belt body 105, the above two LEDs 2101, 2102 are disposed right and left (with an equal interval in this example), by which the belt body is mounted so that the irradiation light emitted from the LEDs 2101, 2102 is irradiated to a part of the body (back 3 of the hand or the palm 30 or finger 33 through the back 3 of the hand in this example) of the operator M. That is, the LEDs 2101, 2102 and the photodetectors 2106a to 2106d, 2107a to 2107d are arranged opposing the back 3 of the hand of the operator M when the belt body 105 is mounted on the wrist (See FIG. 22). And the photodetectors 2106a to 2106d, 2107a to 2107d are provided in correspondence with the arrangement of the LEDs 2101, 2102 as shown in FIG. 21 so that the reflection light or scattering light is received at the irradiation portion of the irradiation light irradiated from the LEDs 2101, 2102 to a part of the body of the operator M (back 3 of the hand or palm 30 or finger 33 through the back 3 of the hand in this example). Particularly, the arrangement is made such that the reflection light or scattering light at the irradiation portion of the irradiation light irradiated from the light-emission side LED 2101 is received at the photodetectors 2106a to 2106d, and the irradiation light irradiated from the light-emission side LED 2102 is similarly received by the photodetectors 2107a to 2107d.

Further, in this example, each of the photodetectors 2106a to 2106d, 2107a to 2107d is arranged so that their focus positions are located in the vicinity of the palm 30 of the operator M. As a result, the attitude of the palm and the like of the operator can be detected surely with high accuracy.

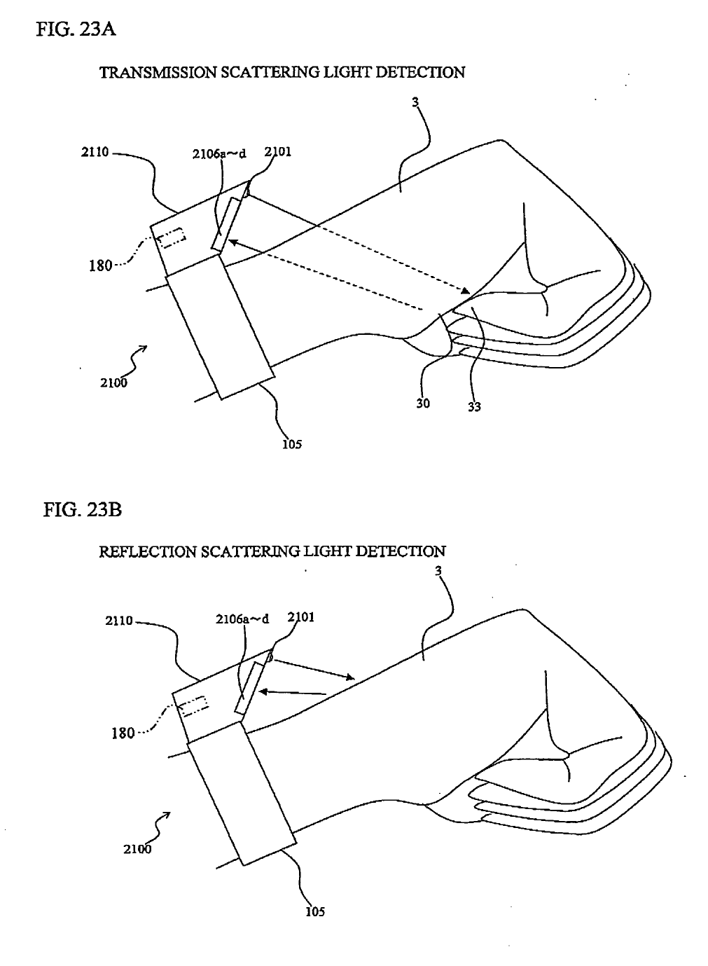

FIGS. 23A and 23B are diagrams illustrating examples of the light-receiving behavior of such irradiation light. In the example shown in FIG. 23A, the transmission scattering light at the palm 30 or the finger 33 of the irradiation light irradiated from the LED 2101 so as to penetrate the back 3 of the hand from the front side to the back side penetrates the back 3 of the hand again from the back side to the front side and is received by the photodetectors 2106a to 2106d (attitude of the palm 30 or finger 33 or a change in the attitude is mainly detected). In the example shown in FIG. 4B, a state is shown that the reflection scattering light at the back 3 of the hand of the irradiation light irradiated from the LED 2101 is received by the photodetectors 2106a to 2106d (the attitude of the palm 30 and a change in the attitude is detected mainly by the movement on the skin surface of the back 3 of the hand).

As shown in the examples in FIGS. 23A and 23B, in this embodiment, the transmission scattering light or reflection scattering light of the irradiation light irradiated from at least one of the LEDs 2101, 2102 on the back 3 of the hand or the palm 30 or finger 33 is received by the corresponding photodetectors 2106a to 2106d, 2107a to 2107d, and the attitude of the palm or finger of the operator M or a change in the attitude is detected by the pattern of the light-receiving result.

A method of detecting the attitude change of the palm or finger in the above can be conceptually explained similarly using FIG. 5 explained in the first embodiment. That is, in FIG. 5, as mentioned above, the operator M does not make any operation in a time “O” in the figure, while “paper” state is shown in a time “A” in the figure, “scissors” state in a time “B” in the figure, and “stone” state in a time “C” in the figure. By such movement of each finger, positions or states of muscles, blood vessels and the like in the palm 30 or finger 33 of the operator M are changed in coordination, and the above-mentioned behavior of the transmission scattering light and reflection scattering light are changed and as a result, each light-receiving intensity at the photodetectors A to D (the photodetectors 2106a to 2106d or 2107a to 2107d) is changed over time as shown in the figure. By analyzing the change pattern by a predetermined method, the attitude of the palm 30 or finger 33 of the operator M and its change can be detected. Instead of watching of the light-receiving intensity, a pulse light may be irradiated and its attenuation value may be detected, for example.

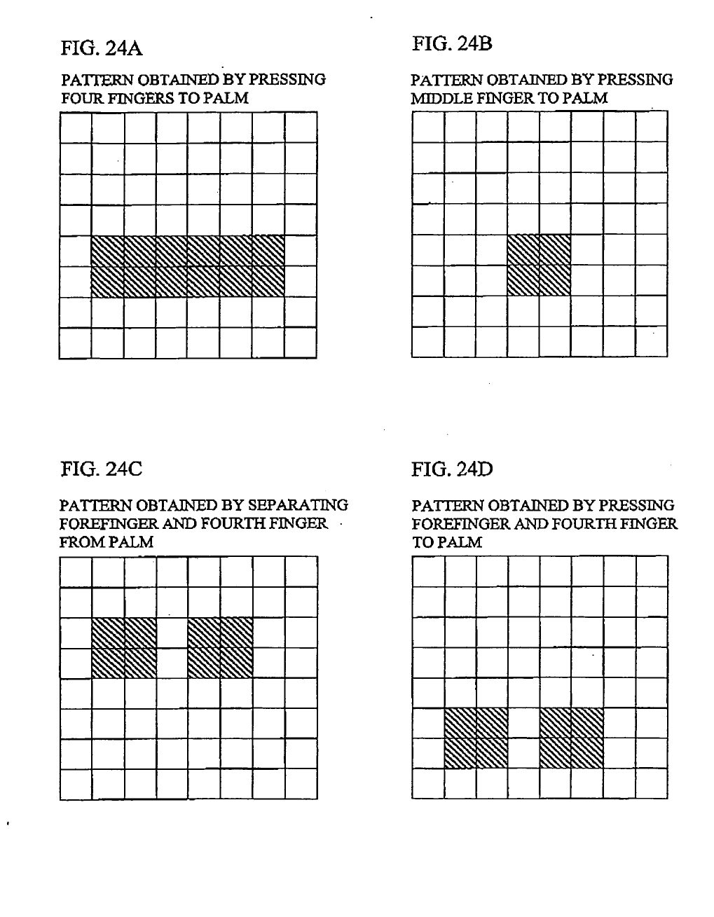

FIGS. 24A to 24D are diagrams illustrating an example of patterns detected by the above detecting method. In this example, the pattern seen from the palm 30 side of the operator M is shown. Further, the example of light receiving by 8×8 photodetectors with higher density as the photodetector is shown. In the example of FIG. 24A, a detection pattern of a state where four fingers 33 (forefinger, middle finger, fourth finger, little finger) are pressed onto the palm 30 is shown. In the example of FIG. 24B, a state where the middle finger is pressed onto the palm 30, in the example of FIG. 24C, a state where the forefinger and the fourth finger are (slightly) separated from the palm 30 (or gradually separated from the palm 30), and in the example of FIG. 24D, a state where the forefinger and the fourth finger are pressed onto the palm 30 are shown, respectively.

By detecting the attitudes and the like of the finger 33 or palm 30 of the operator M, an operation reflecting the intension of the operator M with high accuracy is realized, and when the operator M moves at least one (one to five for a hand) finger 33, it can be detected as a light-receiving pattern. If the operation by the finger 33 above is possible, an input method equivalent to a mouse or keyboard, or an operation by multi-tap input equivalent to a mobile phone is also made possible. In the above examples, the operation can be used in such a way that the pattern shown in FIG. 24A is set as start operation of the operating apparatus 2100 or the patterns in FIGS. 24B to 24D are considered as the input method using a mouse in which the pattern in FIG. 24B as an operation corresponding to a right click, the pattern shown in FIG. 24C to an upward scroll, and the pattern shown in FIG. 24D to a downward scroll and the like. If keyboard display or the like is made in the display device 300, which will be described later, input equivalent to a keyboard is also made possible (input on a virtual keyboard, blind touch). The multi-tap input in the mobile phone and the like is also made possible.

At this time, by providing a reflecting body that increases intensity of reflection light or scattering light at the finger 33 of the irradiation light at the finger 33 of the operator M (applying a reflecting paint on a nail, placing a cap provided with a reflecting body material over the finger 33 and the like for example), the attitude and the like of the finger 33 of the operator M can be detected with higher accuracy.

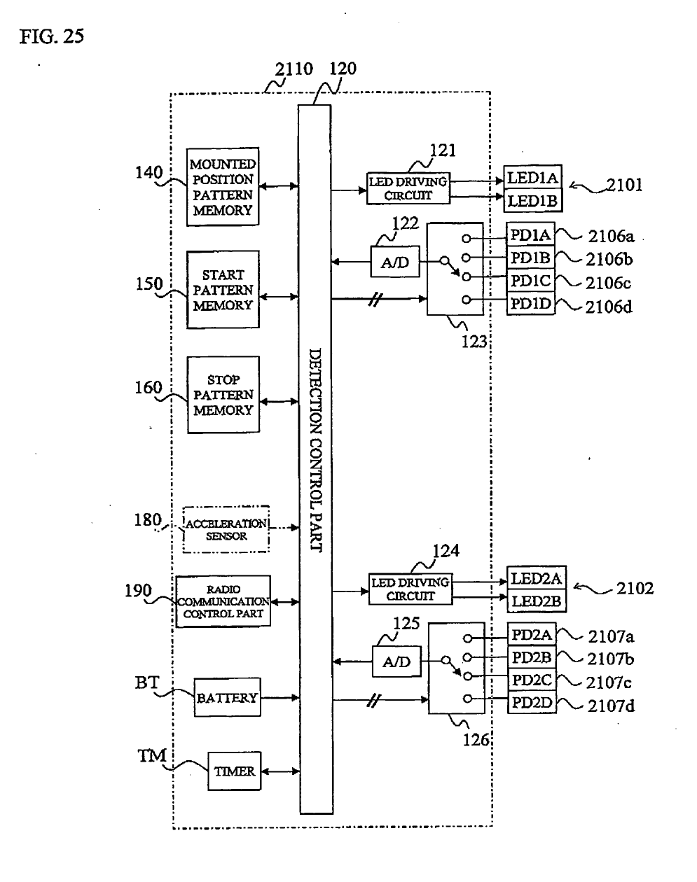

FIG. 25 is a functional block diagram illustrating a control system including the detection controller 2110 provided at the operating apparatus 2100 in order to realize the above method and corresponds to FIG. 6 in the first embodiment. The same reference numerals are given to portions equivalent to those in FIG. 6.

In FIG. 25, the detection controller 2110 is provided with, similar to the controller 110, the detection control part 120, the LED driving circuits 121, 124, switches 123, 126, the A/D converters 122, 125, the mounted position pattern memory 140, the start pattern memory 150 and the stop pattern memory 160, the radio communication control part 190, the battery BT for power supply, and the timer TM.

The LED driving circuits 121, 124 drive the LEDs 2101, 2102, respectively, on the basis of a control signal from the detection control part 120. The switches 123, 126 selectively input the respective output signals (light-receiving signal) at the photodetectors 2106a to 2106d, 2107a to 2107d. The mounted position pattern memory 140 is used for specification of the mounted position of the belt body 105 capable of parallel movement front and rear (depth direction) with respect to the wrist 2 and relative rotation with respect to the wrist 2 (details will be described later).

In the LEDs 2101, 2102, those with different wavelength or LED1A, LED2A, which are visible light LEDs in this example, and LED1B, LED2B, which are near infrared light LEDs, are contained in a single package, respectively. At the visible light LED and the infrared light LED, the visible light emission and near infrared light emission are switched as will be described later by the respective driving circuits 121, 124 (or they may be emitted at the same time if they can be separated by a filter in a variation, which will be described later).

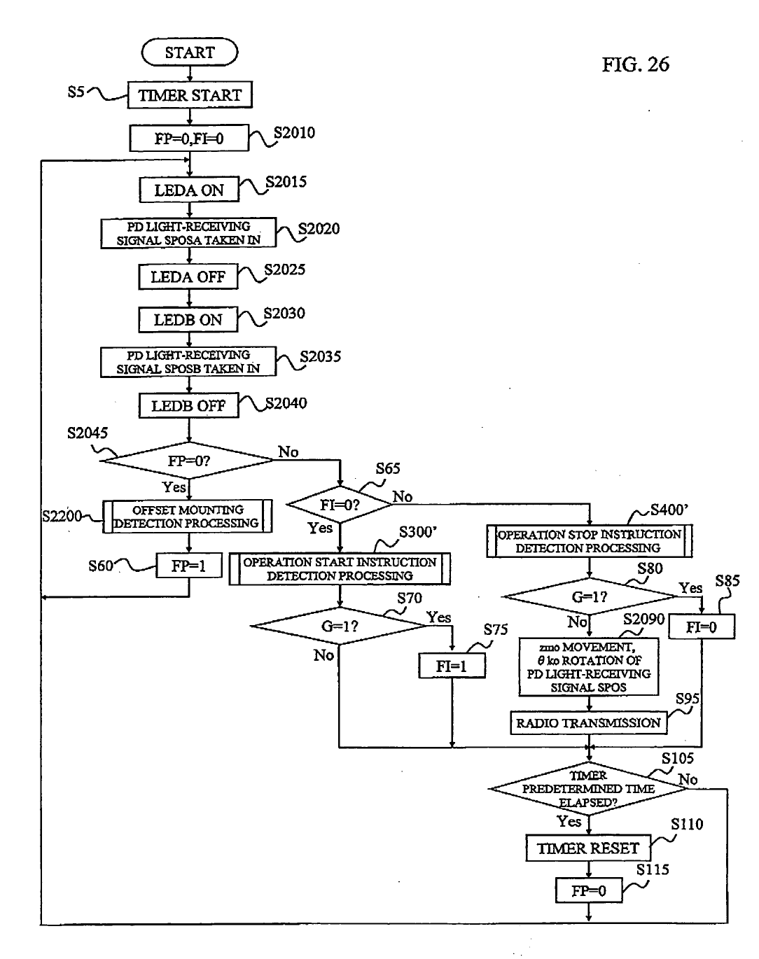

FIG. 26 is a flowchart illustrating an example of a control procedure executed by the detection control part 120 and corresponds to FIG. 7 in the first embodiment.

In the flow shown in FIG. 26, first, at Step 5 similar to FIG. 7, count of the timer TM is started.

Subsequently, the routine goes to Step S2010 corresponding to Step S10, where similarly to Step S10, a mode flag (flag indicating if it is in the operation mode or offset mounting detection mode. Details will be described later) is initialized to FP=0 and an operation flag (flag indicating if it is during operation input or waiting for operation start instruction in the operation mode. Details will be described later) is initialized to FI=0.

Subsequently, the routine goes to Step S2015 corresponding to Step S15, where similarly to Step S15, a control signal is outputted to the LED driving circuits 121, 124 corresponding to the LEDs 2101, 2102 so that light emission of the LEDs 2101, 2102 is started. At this time, in this example, as shown in the above FIG. 25, the two LEDs 2101, 2102 with the wavelengths different from each other (visible light LED and near infrared light LED in the above example) are made as a pair and a first LED 2101a (indicated as “LED1A” in FIG. 7), a second LED 2101b (indicated as “LED1B” in FIG. 25), a first LED 2102a (indicated as “LED2A” in FIG. 7), and a second LED 2102b (indicated as “LED2B” in FIG. 25) are provided. At Step S2015, the first LED 2101a, first LED 2102a are light-emitted.

Subsequently, the routine goes to Step S2020 corresponding to Step S20, where a light-receiving result signal SposA at each of the photodetectors 2106a to 2106d, 2107a to 2107d by light emission of the first LED 2101a, 2102a at Step S2015 is taken in (and temporarily stored in an appropriate memory device). That is, while the switch 123 is switched, the light-receiving signal at the photodetectors 2106a, 2106b, 2106c, 2106d is sequentially taken in through the A/D converter 122, and while the switch 126 is switched, the light-receiving signal at the photodetectors 2107a, 2107b, 2107c, 2107d is sequentially taken in through the A/D converter 125 (therefore, in this example, eight light-receiving signals are taken in to the light emission of the single first LED 2101a, 2102a).

Subsequently, the routine goes to Step S2025 corresponding to Step S25, where similarly to Step S25, a control signal is outputted to the LED driving circuits 121, 124 corresponding to the LED 2101, 2102 which started light emission at Step S2015 and light emission of the first LED 2101a, 2102a is stopped.

Subsequently, the routine goes to Step S2030 corresponding to Step S30, where similarly to Step S2015, a control signal is outputted to the LED driving circuits 121, 124 and light emission of the second LED 2101b, 2102b is started, respectively.

And at Step S2035 corresponding to Step S35, similarly to Step S2020, a light-receiving result signal SposB at each of the photodetectors 2106a to 2106d, 2107a to 2107d by the light emission of the second LED 2101b, 2102b at Step S2030 is sequentially taken in through the A/D converters 122, 125 while the switches 123, 126 are sequentially switched (similarly to the above, eight light-receiving signals are taken in to light emission of the single second LED 2101b, 2102b and temporarily stored in an appropriate memory device).

Subsequently, the routine goes to Step S2040, corresponding to Step S40, where a control signal is outputted to the LED driving circuits 121, 125 corresponding to the LED 2101, 2102 which started light emission at Step S2030, and the light emission of the second LED 2101b, 2102b is stopped.

And the routine goes to Step S2045 corresponding to Step S55. At step S2045, it is determined if the mode flag FP=0 or not. Since it is FP=0 at Step S2010 at first, the determination is satisfied, and the routine goes to Step S2200 provided in correspondence with Step S200.

At Step S2200, on the basis of the check between the light receiving pattern taken in at Step S2015 to Step S2040 as above and the pattern stored in the mounted position pattern memory 140 (details will be described later), offset mounting detection processing for detecting a relative position of the belt body 105 mounted on the wrist 2 (a position in the front and rear (depth) direction with respect to the wrist 2 and a position in the rotating direction around the wrist 2) is carried out and the mounted positions in the depth direction and rotating direction (mounted distance zmo, mounting angle θko, for both, details will be described later) are determined.

When the offset mounting detection processing of the belt 105 is completed at Step S2200, at Step S60 similar to the above, the mode flag FP is changed to FP=1, which is the operation mode, and the routine returns to Step S2015. And similarly to the above, after the light-receiving results are taken in by repeating Step S2015 to Step S2040 again, since it is FP=1, the determination at Step S2045 is not satisfied any more, and the routine goes to Step S65 similar to the above.

At Step S65, it is determined if the operation flag FI=0 or not. First, since it is FI=0 as it is still in the initialized state at the above Step S2010, the determination is satisfied, and the routine goes to Step S300′ instead of Step S300.

At Step S300′, on the basis of the check between the light-receiving pattern taken in at Step S2015 to Step S2045 as above and the pattern stored in the start pattern memory 150 (details will be described later), the operation start instruction detection processing for detecting whether the operation (of the finger 33 in this example) by the operator M intends operation start or not is executed.

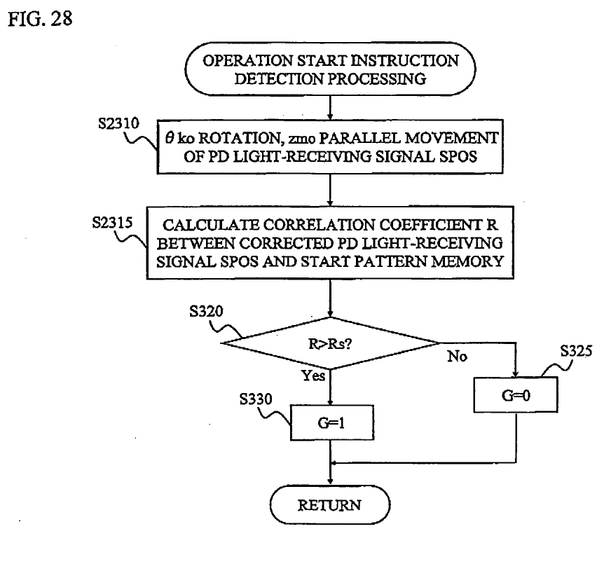

Subsequently, the routine goes to Step S70 similar to the above, where it is determined if the flag G indicating recognition/unrecognition of the instruction is 1 or not. If the operation start instruction has been recognized at Step S300′, it is G=1 (See Step S330 in FIG. 28, which will be described later) and the determination is satisfied, the operation flag FI=1 is set at Step S75 similar to the above, and the routine goes to Step S105 similar to the above. If the oration start instruction has not been recognized at Step S300′, since it is G=0 (See Step S325 in FIG. 28, which will be described later), the determination is not satisfied, and the routine goes to Step S105 as it is.

At Step S105, similarly to the above, it is determined if a predetermined time set in advance has elapsed or not since time count by the timer TM at Step S5 is started. The determination is not satisfied till the time has elapsed, and the routine returns to Step S2015, where the same procedure is repeated. If the operation start instruction is not recognized yet at Step S300′ and it is still G=0, Step S105->returning to Step S2015 and repeating of the subsequent Step, via Step S65 and then, at Step S300′, the operation start instruction is detected again and while the predetermined time has not elapsed yet, these procedures are repeated till the operation start instruction is recognized and it becomes G=1.

If it becomes G=1 by recognition of the operation start instruction, since it is FI=1 at Step S75, the routine returns to Step S2015 as above, through Step S2015 to Step S2045 and the determination at Step S65 is not satisfied and the routine goes to Step S400′.

At Step S400′, on the basis of the check between the light-receiving pattern taken in at Step S2015 to Step S2040 as above and the pattern stored in the stop pattern memory 160 (details will be described later), the operation stop instruction detection processing for detecting if the operation (of the finger 33 in this example) by the operator M is intended to stop the operation or not is executed.

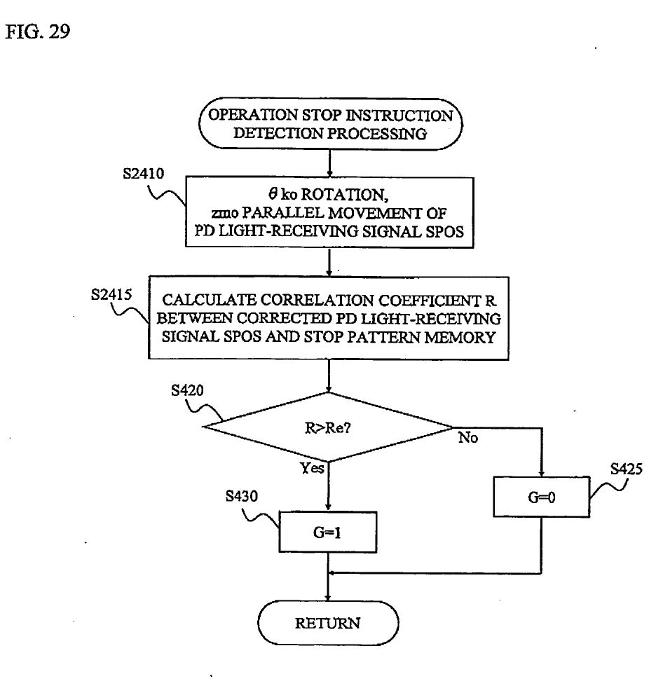

Subsequently, the routine goes to Step S80 similar to the above, where it is determined if the flag G indicating recognition/unrecognition of the instruction is 1 or not. If the operation stop instruction has not been recognized yet at Step S400′, since it is G=0 (See Step S425 in FIG. 29, which will be described later), the determination is not satisfied and the routine goes to Step S2090 provided in correspondence with Step S90.

At Step S2090, the light-receiving results signals SposA and SposB obtained at Step S2015 to Step S2040 after the operation start instruction and before the operation stop instruction are considered to be the original operation manipulation corresponding to the operation intension of the operator M, correction is made to carry out frontward or rearward parallel movement in the depth direction by the mounted distance zmo detected at Step S2200, the correction is also made to carry out rotation by the mounted angle θko, and a light-receiving correction signal is created.

Subsequently, at Step S95, similarly to the above, a control signal is outputted to the radio communication control part 190 and the light-receiving correction signal created at Step S2090 is transmitted to the controller 200 via radio communication and the routine goes to Step S105.

On the other hand, if the operation stop instruction is recognized at Step S400′ at the above-mentioned Step S80, since it is G=1 (See Step S430 in FIG. 29, which will be described later), the determination is satisfied, the operation flag FI is returned to 0 at Step S85 similar to the above, and the routine goes to Step S105

At Step S105, the determination is not satisfied till the above-mentioned predetermined time has elapsed, and the routine returns to Step S2015 and the same procedure is repeated. And after Step S105->Step 2015 to Step S2045, the determination at Step S65 is satisfied, the operation start instruction is detected at Step S300′ again, and these procedures are repeated till the operation start instruction is recognized while the above predetermined time has not elapsed.

If the above-mentioned time count by the timer TM reaches the above predetermined time while the procedure from Step S2015 to Step S105 as above is repeated, the determination at Step S105 is satisfied similarly to the above, the routine goes to Step S110, a control signal is outputted to the timer TM so as to reset (initialize) the time count and then, in order to start from the detection of the offset mounting again, the mode flag is returned to FP=0 at Step S115, and the routine returns to Step S2015 and same procedure is repeated.

Subsequently, the offset mounting detection processing at Step S200 will be described. In this embodiment, in a predetermined state of the wrist 2 of the operator M (when a power of the palm 30 is released to the most natural state, for example), with distribution of the light-receiving signals (light-receiving pattern) at the photodetectors 2106a to 2106d, 2107a to 2107d of the irradiation light from the LED 2101, 2102 as an index, how much the light-receiving signal distribution has been rotated by the rotation of the belt body 105 around the wrist 2 is detected by checking with the light-receiving pattern table stored in the mounted position pattern memory 140. Further, at this time, how much the light-receiving signal distribution has moved frontward or rearward from the position in the depth direction of the belt body 105 around the wrist 2 is detected by checking with the light-receiving pattern table stored in the mounted position pattern memory 140.

That is, though detailed illustration is omitted, the light-receiving pattern table stores the light-receiving patterns (reference position light-receiving pattern) at the reference position with a given state (with the back 3 of the hand on the front side when seen from the operator M, when the LED 2101 and the LED 2102 are located with an equal interval to the center part in the width direction of the back 3 of the hand, for example) is set as the reference position (θ=0°) in the rotating direction. And the detection control part 120 creates a pattern obtained by rotating the above light-receiving pattern for a predetermined angular interval (here, by 5.625° obtained by dividing the 90° range by 16) on the basis of the light-receiving pattern at the above-mentioned reference position and temporarily stores it in an appropriate memory, not shown. At this time, each value of −8 to 8 is made to correspond to a variable k (rotation offset position count variable) that counts an offset position in the rotating direction from the reference position at every predetermined angular interval (in the example of the above 16-division). Each value of k=−8 to 8 corresponds such that k=0 to an angular position θ=0° (reference position per se), k=−8 corresponds to the angular position θ=45°, and the same applies to the following similarly to k=8 corresponding to the angular position θ=45°.

Further, on the basis of the light-receiving pattern at the reference position, each value such as 0 to 15 is made to correspond to a variable m (depth offset position count variable) that counts an offset position in the depth direction from the reference position by every predetermined distance interval (1 mm in this example). In this example, since the offset to front or rear of the reference position is detected for the offset position in the depth direction, m=7 is made to correspond to the reference position.

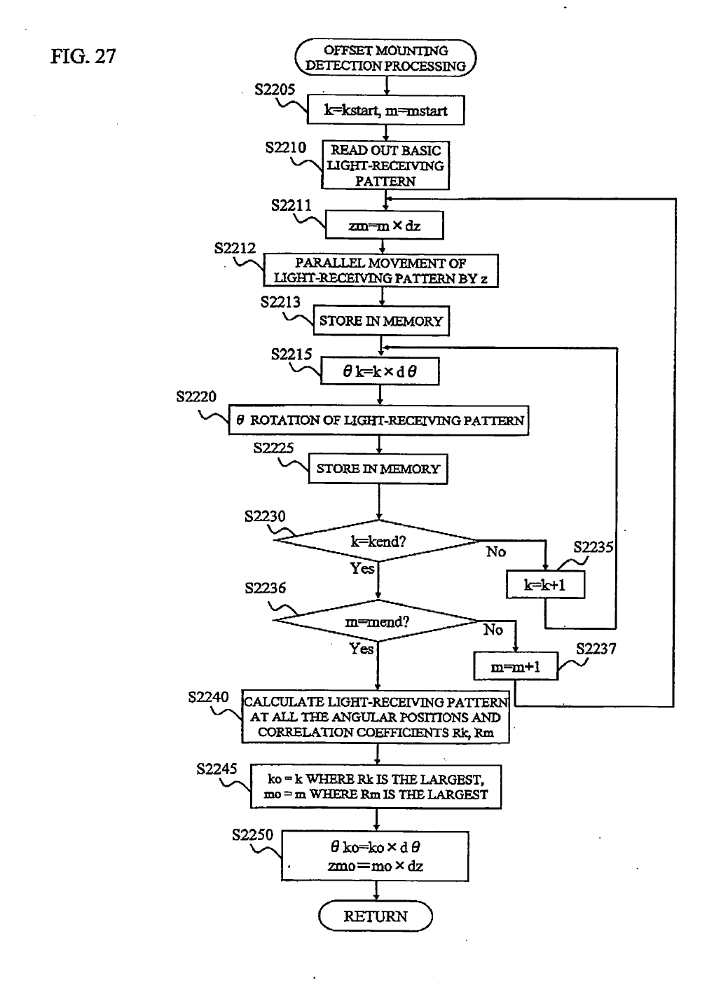

FIG. 27 is a flowchart illustrating a detailed procedure of Step S2200.

At Step S2205, first, values of the rotation offset position count variable k and the depth offset position count variable m are set to their initial values kstart (k=−45° in this example), mstart (m ˜0 mm in this example). The values of kstart, mstart may be set in a fixed manner or may be operated (or selected) and inputted by the operator every time.

And at Step S2210, the basic light-receiving pattern corresponding to the above kstart (−45° in this example), the above mstart (m=0 mm in this example) is read out of the mounted position pattern memory 140 and temporarily stored in an appropriate memory.

Subsequently, the routine goes to Step S2211, where using the above-mentioned predetermined distance interval dz (1 mm in this example), a distance position zm=k×dz corresponding to each depth offset position variable z is defined.

And at Step S2212, such distribution is provided that the basic light-receiving pattern (corresponding to m=mstart) obtained at Step S2210 and stored in the memory is parallel moved (offset) by the mounted distance z acquired at Step S2211 and stored in the memory at Step S2213.

Subsequently, the routine goes to Step S2215, where using the above-mentioned predetermined angular interval dθ (5.625° in this example), the angular position θk=k×dθ corresponding to each rotation offset position variable k is defined.

And at Step S2220, such distribution is provided that the basic light-receiving pattern (corresponding to k=kstart) obtained at Step S2210 and stored in the memory is rotated (offset) by the mounted angle θk acquired at Step S2215 and stored in the memory at Step S2225.

Subsequently, it is determined at Step S2230 whether k has reached a predetermined rotation complete value kend set in advance or not. The value of kend may be set in a fixed manner or may be operated (or selected) and inputted by the operator every time. In the case of k<kend, the determination is not satisfied, 1 is added to k at Step S2235, and the routine returns to Step S2215, where the same procedure is repeated.

In the case of k=kend, the determination at step S2230 is satisfied, and the routine goes to Step S2236.

And at Step S2236, it is determined whether m has reached a predetermined parallel movement complete value mend set in advance. The value of mend may be set in a fixed manner or may be operated (or selected) and inputted by the operator every time. In the case of m<mend, the determination is not satisfied, 1 is added to m at Step S2237, and the routine returns to Step S2211, where the same procedure is repeated.

In the case of m=mend, the determination at Step S2236 is satisfied, and the routine goes to Step S2240.

At Step S2240, by multiplying distribution of all the light-receiving result signals Spos (may be a light-receiving signal of any of the LEDs 2101, 2102 and may be either one of the first LED and the second LED) obtained at Step S2015 to Step S2040 in above-mentioned FIG. 26 at this time by each value of each light-receiving pattern of m=mstart to mend and k=kstart to kend stored and accumulated in the memory at Step S2213 and S2225, a correlation coefficient Rm, Rk are calculated for each offset position variable m and k.

Subsequently, at Step S2245, on the basis of the result at Step S2240, the offset position variables k and z where the correlation functions Rk, Rm are the largest are set as offset positions ko, mo corresponding to the position of the current actual belt body 105.

And at Step S2250, the mounted angle θko and the mounted distance zmo of the actual belt body 105 are calculated by θko=ko×dθ and zmo=mo×dz, using ko, mo calculated at Step S2245 and the above-mentioned dθ, dz, and this flow is finished.

FIG. 28 is a flowchart illustrating a detailed procedure of Step S300′ and corresponds to FIG. 10 in the first embodiment.

In FIG. 28, first, at Step 2310 corresponding to the above-mentioned Step S310, all the light-receiving result signals Spos (may be a light-receiving signal of any of the LEDs 2101, 2102 and may be either one of the first LED and the second LED) obtained at Step S2015 to Step S2040 in the above-mentioned FIG. 26 at this time is rotated by the mounted angle θko of the belt body 105 calculated at the previous Step S2200 for rotation position correction. Further, parallel movement is made by the mounting distance zmo for depth position correction.

Subsequently, the routine goes to Step S2315, where a light-receiving pattern corresponding to a start instruction operation (such as putting three fingers of forefinger, middle finger, fourth finger to the palm, for example) of the finger 33 determined in advance as a cue (trigger signal) to start detection of the operation manipulation by the operator M and stored in the start pattern memory 150 is read out of the start pattern memory 150. And a correlation coefficient R between this read-out start pattern and the light-receiving pattern corrected at Step S2310 is calculated by a predetermined method.

And at Step S320, it is determined if the value of the correlation coefficient R calculated at Step S2310 is larger than a predetermined value Rs set in advance, that can be considered as substantially equal with a considerable probability in view of pattern recognition. In the case of R>Rs, the determination is satisfied, and the routine goes to Step S330, where the flag G indicating recognition/unrecognition of the instruction is set to 1 (recognized). In the case of R≦Rs, the determination is not satisfied, and the routine goes to Step S325, where the flag G is set to 0 (unrecognized). When Step S330 or Step S325 is completed, this flow is finished.

FIG. 29 is a flowchart illustrating a detailed procedure of Step S400′ and corresponds to Step S400 in the first embodiment.

In FIG. 29, first, at Step S2410 corresponding to Step S410, all the light-receiving result signals Spos (may be a light-receiving signal of any of the LEDs 2101, 2102 and may be either one of the first LED and the second LED) obtained at Step S2015 to Step S2040 in FIG. 26 at this time is rotated by the mounted angle θko of the belt body 105 calculated at the previous Step S2200 for rotation position correction. Further, parallel movement is made by the mounting distance zmo for depth position correction.

Subsequently, the routine goes to Step S2415 corresponding to Step S415, where a light-receiving pattern corresponding to a stop instruction operation (such as putting only the thumb to the palm and the like, for example) of the finger 33 determined in advance as a cue (trigger signal) to stop detection of the operation manipulation by the operator M and stored in the stop pattern memory 160 is read out of the stop pattern memory 160. And a correlation coefficient R between this read-out stop pattern and the light-receiving pattern corrected at Step S2410 is calculated with a predetermined method.

And at Step S420 similar to the above, it is determined if the value of the correlation coefficient R calculated at Step S2410 is larger than a predetermined value Re set in advance, that can be considered as substantially equal with a considerable probability in view of pattern recognition. In the case of R>Rs, the determination is satisfied, and the routine goes to Step S430 similar to the above, where the flag G indicating recognition/unrecognition of the instruction is set to 1 (recognized). In the case of R≦Re, the determination is not satisfied, and the routine goes to Step S425 similar to the above, where the flag G is set to 0 (unrecognized). When Step S430 or Step S425 is completed, this flow is finished.

As for the functional configuration of the controller 200 in this embodiment, those equivalent to the ones shown in FIG. 12 are sufficient, and illustration and explanation will be omitted.

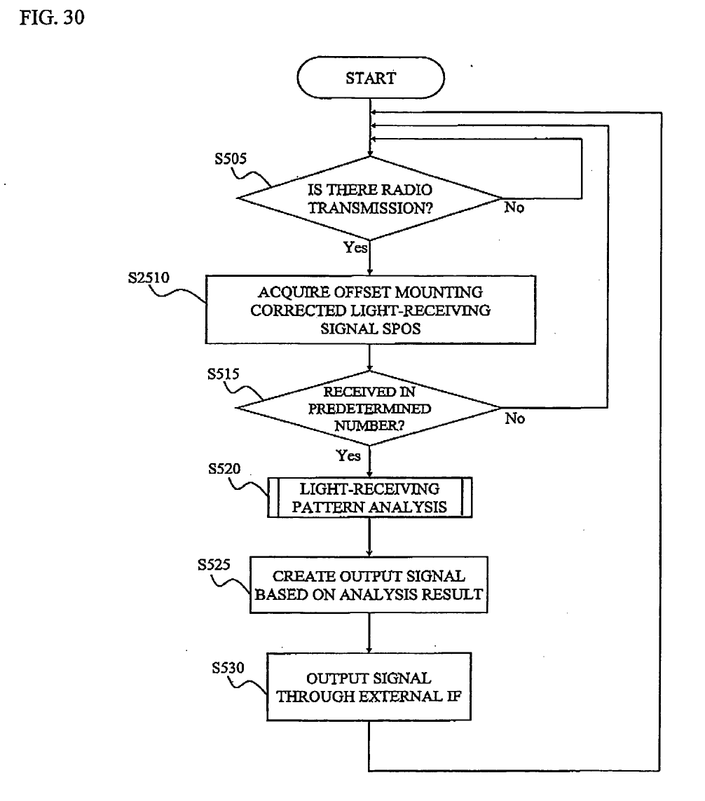

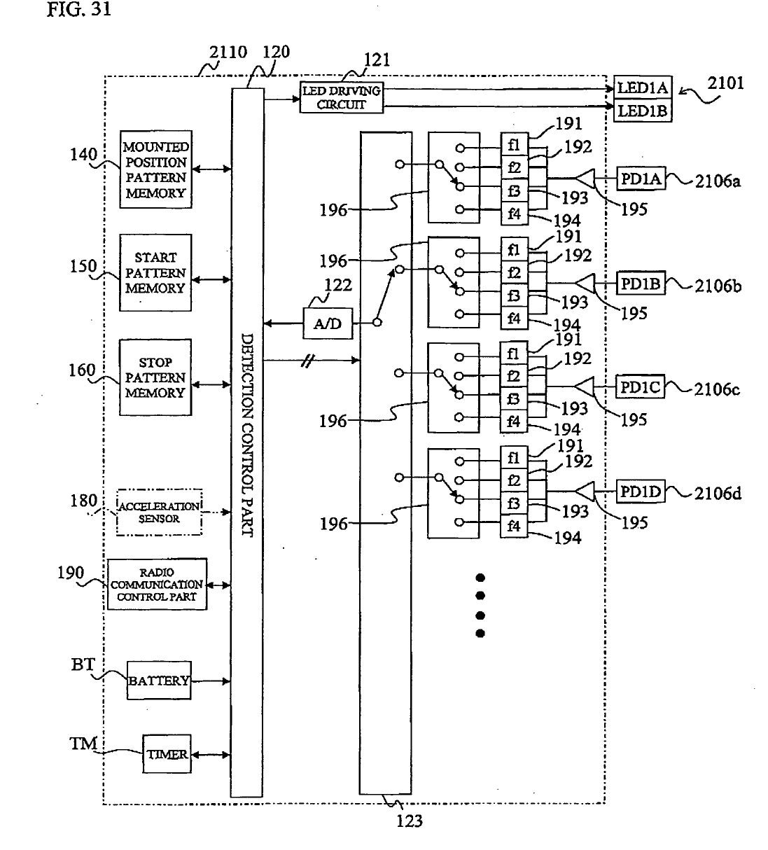

FIG. 30 is a flowchart illustrating an example of a control procedure executed by the entire controller 200 and corresponds to FIG. 13 in the first embodiment. In FIG. 30, provision of Step S2510 instead of Step S510 in FIG. 13 is the only difference.

That is, when Step S505 similar to the above is finished, the routine goes to Step S2510, and at the input signal creation control part 210, a light-receiving correction signal obtained at the above-mentioned Step S2015 to Step S2040 after the operation start instruction and before the operation stop instruction (=SposA and SposB), corresponding to the operation intention of the operator M, and applied with correction of the mounted angle θko and correction of the mounting distance zmo is extracted and obtained from radio signal data from the controller 2100 received at Step S505 and stored and accumulated in an appropriate memory.

Subsequently, Step S515 and after are similar to the above embodiment, and the explanation will be omitted.

The appearance structure of the display device 300 of this embodiment is similar to the one shown in the above-mentioned FIG. 14, and the explanation will be omitted. Further, as for the operating system of this embodiment, an example of an automobile servicing shown in the above-mentioned FIG. 15 can be cited as an actual application example.

In the above, Step S2015 to Step S2040 in the flow executed by the detection control part 120 shown in FIG. 26 constitutes a pattern detecting portion that detects the light-emitting device and at least one light-receiving device that receives reflection light or scattering light of the irradiation light from the light-emitting device in each claim as a light-receiving pattern. Further, Step S95 and the radio communication control part 190 constitute a signal output portion that outputs an operation signal corresponding to an operation state of a finger part of the operator on the basis of the light-receiving pattern detected by the pattern detecting portion.

Further, Step S525 in the flow of FIG. 30 executed by the input signal creation control part 210 of the controller 200 constitutes a second attitude calculating portion that calculates an attitude of the finger part of the operator or a change mode in the attitude on the basis of the light-receiving pattern obtained from the operation signal inputted from the signal output portion.

In the operating system of this embodiment configured as above, when the operator M mounts the operating apparatus 2100 on the wrist 2 through the belt body 105 and moves the palm 33 or the finger 30 with an intention of some operation in that mounted state, the irradiation light emitted from the LEDs 2101, 2102 penetrates the back of the hand from the front side to the back side so as to generate a pattern of the reflection light and scattering light corresponding to the attitude or a change in the attitude in the palm 33 or the finger 30, and then, the light returns while penetrating the back of the hand from the back side to the front side again and is received by the photodetectors 2106a to 2106d, 2107a to 2107d at the respective corresponding positions. As above, since various light-receiving results are created at the plurality of photodetectors 2106a to 2106d, 2107a to 2107d in response to the movement of the finger 33 of the operator M, the operation signal corresponding to the operation state of the finger 33 of the operator M can be outputted on the basis of the combination of the light-receiving results.

As mentioned above, by detecting the attitude and the like of the finger 33 and the palm 30 of the operator M through an optical method as an operation signal and calculating the attitude on the basis of that, an operation reflecting the intention of the operator with a high accuracy can be realized. Further, since it is a non-contact optical method, there is no need to bring an electrode and the like into close contact with the body of the operator M as with the method by muscle potential or acceleration detection, it does not give a sense of pressure or discomfort to the operator M but a comfortable operation can be conducted.

Particularly in this embodiment, the change in distribution of the living body information such as blood vessel distribution/muscle distribution/skin surface shape distribution and the like of the palm 30 or finger 33, which is changed when the operator M changes the attitude of the finger 33 is detected as a change in a behavior of transmission light or scattering light of the irradiation light of the LEDs 2101, 2102, that is, a change in the light-receiving pattern of the photodetectors 2106a to 2106d, 2107a to 2107d. Specifically, the light-receiving pattern obtained in advance at a predetermined reference attitude is held in the light-receiving pattern memory 220 of the controller 200 as the reference attitude light-receiving pattern, and the reference attitude light-receiving pattern and the light-receiving pattern currently detected at the operating apparatus 2100 are compared at the controller 200. On the basis of this comparison, a difference between the current light-receiving pattern and the light-receiving pattern at the reference attitude is known, and the attitude of the finger 33 or hand 30 of the operator M or the change mode of the attitude can be calculated in a form according to the difference.

Further, particularly in this embodiment, since the LEDs 2101, 2102 and the photodetectors 2106a to 2106d, 2107a to 2107d are arranged substantially annularly on the belt body 105, they can be made in a structure that can be easily attached to the wrist as mentioned above or any other parts such as torso, neck, ankle, arm and head of the operator M. It may be made in a structure that can be mounted to a part other than the body of the operator M (made mountable on a ceiling or display panel, for example).

The second embodiment is not limited to the above mode, either, but capable of various variations in a range not departing from its gist and technical idea. The variations will be described below.

(2-1) When a Plurality of Modes are Set:

In the above embodiment, signal output from the operating apparatus 2100 is not carried out all the time but a signal is outputted only when a predetermined start instruction or a predetermined stop instruction was made, but it may be so configured that a plurality of modes relating to the operation of the finger 33 are set in advance and it is determined whether any of the modes is selected (first selection instruction determining portion) so that selection can be made by the selection instruction. As such mode, a mouse mode corresponding to an operation input equivalent to a mouse (See the above-mentioned FIGS. 24B to 24D), a character input mode by key corresponding to an operation input equivalent to a keyboard, or a multi-tap input mode corresponding to an operation input equivalent to a mobile phone may be set in advance. As a result, the operator can select a convenient mode intended by the operator from the mouse mode, character input mode by key or multi-tap input mode for operation, which can improve convenience.

Further, it may be so configured that by holding a plurality of light-receiving patterns obtained in advance at a predetermined attitude as light-receiving pattern for mode instruction corresponding to each of the above modes and by comparing the light-receiving pattern for mode instruction and the light-receiving pattern currently detected by the pattern detecting portion (first mode instruction comparing portion), determination is made on which of the modes was selected on the basis of the comparison (first selection instruction determining portion). As a result, it is only necessary that the operator takes a predetermined attitude corresponding to each mode at mode selection and there is no more need to conduct a special operation other than that. As a result, operation labor can be reduced. In addition, such comparison or determination for mode selection is not limited on that conducted on the operating apparatus 1200 side but may be conducted on the controller 200 side (second selection instruction determining portion, second mode instruction comparing portion). The same effects can be also obtained in these cases.

(2-2) When Light is Emitted at the Same Time Using Filter Device:

In the above embodiment, the LEDs 2101 and 2102 are sequentially emitted (with a predetermined time difference) but not limited to that. That is, similarly to the variation in the first embodiment (1-1), the LEDs 2101, 2102 may be light-emitted at the same time and they may be separated on the light-receiving side to each predetermined wavelength band using a filter device.

FIG. 31 shows one of such variations (in order to prevent complexity of the figure, a part thereof is omitted in the illustration) and corresponds to FIG. 16 in the first embodiment. In this example, the LEDs 2101, 2102 are modulated by the above corresponding LED driving circuits 121, 124 with modulation frequencies f1, f2, f3, f4 different from each other for irradiation. And in response to that, the amplifier 195 that amplifies a signal received at each of the photodetectors 2106a to 2106d, 2107a to 2107d, the electric filters 191, 192, 193, 194 (filter devices), similar to the above, which extracts and separates them according to the above modulation frequencies f1, f2, f3, f4, and the switch 196 are provided.

In this case, the irradiation light emitted from the LEDs 2101, 2102, which are applied with simultaneous light-emission control (=simultaneous light-emission control portion), and received at the photodetectors 2106a to 2106d, 2107a to 2107d at the same time is separated to each of the predetermined modulation frequency bands (modulation frequencies f1, f2, f3, f4 in this example) at each of the filters 191, 192, 193, 194 and then, inputted to the detection control part 120 through the switch 196 and the switches 123, 126 so that separate detection processing can be executed for each irradiation light of each of the LEDs 2101, 2102. And by receiving the light emitted at the same time without carrying out the light emission with a time difference, time required for light emission and light receiving can be reduced and efficient detection can be made as compared with the sequential light emission as in the above second embodiment.

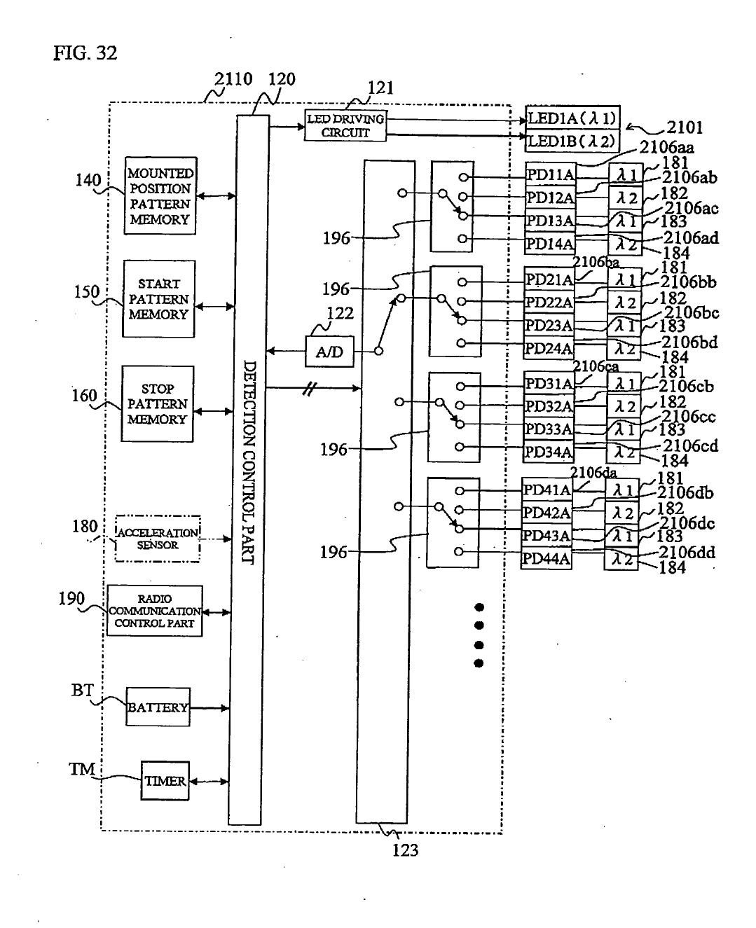

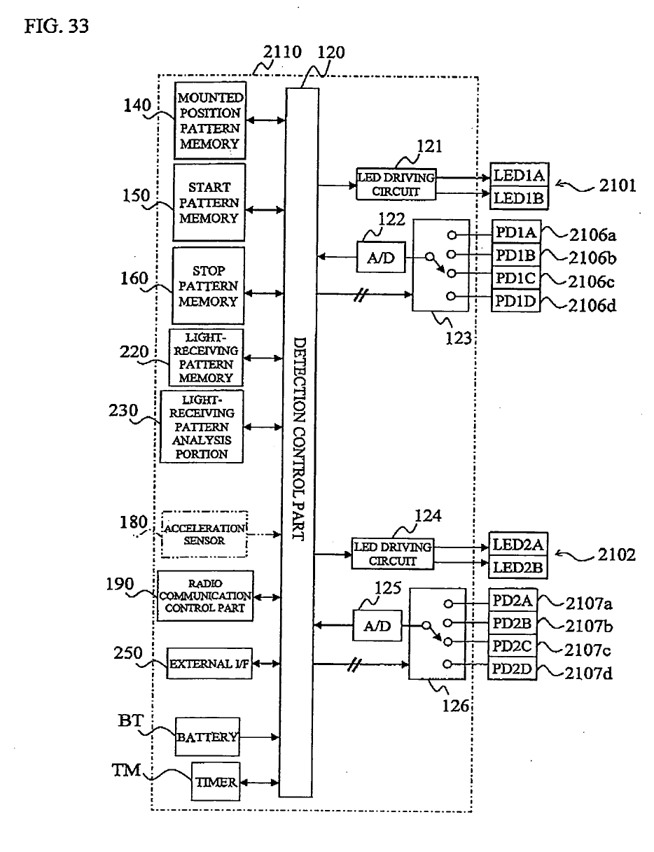

FIG. 32 illustrates another variation using the filter device (in order to prevent complexity of the figure, a part thereof is omitted in the illustration). Similarly to the above-mentioned variation described in (1-1) using FIG. 17, the LEDs 2101, 2102 irradiate wavelengths λ1, λ2, λ3, λ4, which are different from each other, corresponding to LED1A, LED1B. In correspondence with that, the photodetectors 2106a to 2106d, 2107a to 2107d are provided in the number corresponding to the above wavelengths λ1, λ2 (two in this example) each (for the photodetector 2106a, for example, the photodetectors 2106aa, 2106ac corresponding to the wavelength λ1 and the photodetectors 2106ab, 2106ad corresponding to the wavelength λ2). Moreover, as a filter device configured to extract and separate the received light component by the above wavelength and supply those four photodetectors, a physical spectral filter (λ1) 181, a spectral filter (λ2) 182, a spectral filter (λ1) 183, a spectral filter (λ2) 184 are provided.

In this case, similarly to the above variation, the irradiation light emitted from the LEDs 2101a, 2101b, which are applied with simultaneous light-emission control (=simultaneous light-emission control portion), is separated at the same time by predetermined wavelength band (wavelengths λ1, λ2, in this example) at each filter 181, 182, 183, 184 and received and then, supplied to the photodetectors 2106aa, 2106ab, 2106ac, 2106ad, the photodetectors 2106ba, 2106bb, 2106bc, 2106bd and moreover inputted to the detection control part 120 through the switch 196 and the switches 123, 126 so that separate detection processing can be executed for each irradiation light of each of the LEDs 2101a, 2101b. And by receiving the light emitted at the same time without carrying out the light emission with a time difference by light-emission wavelength, time required for light emission and light receiving can be reduced and efficient detection can be made as compared with the sequential light emission as in the above embodiment.

(2-3) When Neural Network Method is Used:

Similarly to the explanation in the variation of (1-2) in the first embodiment using FIG. 18, in the second embodiment, too, the neural network method using the weighted repeat calculation can be used to detect how much the current light-receiving pattern is offset in the rotating direction for the offset correction in the rotating direction and depth direction of the belt body 105.

Since the method and principle of the neural network are similar to and sufficient with the description using the above-mentioned FIG. 18, detailed explanation will be omitted. By making comparison with the neural network method, the reference attitude light-receiving pattern and the light-receiving pattern detected by the pattern detecting portion can be compared, by which the attitude or the change mode in the attitude can be calculated by second attitude calculating portion.

(2-4) When Attitude Analysis is Also Conducted on the Operating Apparatus 2100 Side:

In the above, on the operating apparatus 2100 side, only the detection of the operation start instruction and operation stop instruction and offset correction of the light-receiving signal are performed, and the attitude analysis of the palm 30 and the finger 33 of the operator M on the basis of the light-receiving signal reflecting the behavior of the transmission scattering light or reflection scattering light at the palm 30 and the finger 33 corresponding to the operation intension of the operator M is carried out on the controller 200 side. However, such attitude analysis function and others may be carried out by the operating apparatus 2100, not on the controller 200 side similarly to the description in the variation of the above (1-4).

FIG. 33 is a functional block diagram illustrating a control system in this variation and corresponds to the above-mentioned FIG. 25 and FIG. 19 of the variation of the first embodiment. The same reference numerals are given to portions equivalent to those in FIG. 25, FIG. 202, FIG. 19 and the like and explanation will be omitted or simplified as appropriate.

In the detection controller 2110 shown in FIG. 33, the light-receiving pattern memory 220 in which the reference attitude light-receiving pattern corresponding to the attitude of the operation portion (finger 3, palm 30 and the like) of the operator M in each operation mode is stored and held in the second embodiment, the light-receiving pattern analysis portion 230 (learning processing portion 231 is not shown) that analyzes the operation mode (intension) of the operator, and the external input/output interface (I/F) 250 for radio communication with external equipment (display device 300 and the like) other than the operating apparatus 2100 provided on the side of the controller 200 in the second embodiment are provided.

In this variation, the detection control part 120 of the detection controller 2110 also performing a function of the input signal creation control part 210 of the controller 200 and other portions execute the control procedure equivalent to the flow chart shown in FIG. 30. That is, in the procedure equivalent to Step S505 (hereinafter referred to simply as Step S505), it is determined if the light-receiving signal data has been inputted (or accumulated) at the detection control part 120. If there has been data input or accumulation, the determination is satisfied and at Step S2510, at the detection control part 120, the light-receiving correction signal corresponding to the operation intention of the operator M obtained by the above-mentioned Step S2015 to Step S2040 after the operation start instruction and before the operation stop instruction (=SposA and SposB) and further applied with the mounting distance zmo and mounted angle θko corrections is extracted and obtained from the signal data identified at Step S505 and stored and accumulated in an appropriate memory.

Subsequently, the routine goes to Step S515, where at the detection control part 120, it is determined if the data obtained at Step S2510 has been accumulated in the predetermined number (the number of attitudes of finger 33 or palm 30 sufficient to constitute a single operation mode by the hand of the operator M, for example) or not, and if the accumulated data has reached the predetermined number, the routine goes to Step S520, where at the light-receiving pattern analysis portion 230, referring to the light-receiving pattern (reference attitude light-receiving pattern) stored in the light-receiving pattern memory 220 for identification of the attitude of the finger 33 or palm 30 of the operator, by comparing the reference attitude light-receiving pattern and the light-receiving pattern on the basis of the above accumulated operation signal, the attitude of the finger 33 or palm 30 of the operator M (any of “stone”, “paper”, “scissors” and the like, for example) is analyzed. Moreover, using the plurality of analysis results of the attitude of the finger 33 or palm 30 of the operator M, the operation mode of the operator M (operation intention “stone->scissors->paper” and the like) is analyzed on the basis of the continuity.

Subsequently, the routine goes to Step S525, where at the detection control part 120, on the basis of the operation mode of the operator M analyzed at Step S520, a corresponding operation signal (“open file”, “display next page” and the like, for example) is created and at Step S530, by the external input/output interface 250, the operation signal created at Step S525 is outputted via radio communication to the display device 300 (head-mount display), and the routine returns to Step S505 and the similar procedure is repeated.

In the above, Step S525 in the flow of FIG. 30 executed by the detection control part 120 constitutes a second attitude calculating portion that calculates the attitude of the finger part of the operator or a change mode of the attitude on the basis of the light-receiving pattern obtained from the operation signal inputted from the signal output portion. Further, Step S520 constitutes a second comparing portion for attitude detection that compares the reference attitude light-receiving pattern set according to the living body information distribution corresponding to the predetermined reference attitude of the finger part of the operator and the light-receiving pattern detected by the pattern detecting portion.

In this variation, too, the same effect as the above second embodiment is obtained. Further, by providing the function of the controller 200 at the operating apparatus 2100 side, the controller 200 is not needed any more, which can reduce mounting burden and operation labor of the operator M.

(2-5) Others:

(2-5-1) When Acceleration Sensor is Used:

In the above, in the operation start instruction detection processing at Step S300′ whose details is shown in FIG. 26 and the operation stop detection processing at Step S400′, by providing the acceleration sensor 180 at the belt body 105 (See FIGS. 22, 23, 25 and the like) as described in the variation of the above (1-5-1), the start instruction/stop instruction may be given by applying an acceleration not less than a predetermined value by strongly shaking wrist 2 of the operator M. Moreover, the start instruction and stop instruction may be given by a usual operation switch and the like provided at the belt body 105 or other locations. In these cases, too, such an effect can be obtained that comfortable operation can be performed without giving a sense of pressure or discomfort to the operator M.

(2-5-2) When Laser Light is Used:

That is, similarly to the description in the variation of the above (1-5-2), instead of using the LEDs 2101, 2102, a laser diode LD may be used so that light is emitted while one-dimensional or two-dimensional laser light is scanned. By receiving the reflection light or scattering light in the palm 30 or finger 33 of the laser light at the photodetectors 2106a to 2106d, 2107a to 2107d at corresponding positions, an operation signal corresponding to the operating state of the hand or finger of the operator can be outputted by the signal output device.

(2-5-3) Handling Personal Habits of Operator:

In the recognition and the like of the light-receiving pattern mentioned above, similarly to the description in the variation of the above (1-5-3), a function to have personal habits of the operator M, operation frequency of the specific operation portion and the like learned may be provided. For example, the database 260 that stores personal habits, operation frequency information specific to the individual and the like is provided in the controller 200 (See the above-mentioned FIG. 12), and specific operation or operation mode is stored in the database 260 at a predetermined frequency by the learning processing portion 231 provided at the light-receiving pattern analysis portion 230 (or may be initially set for each operator M or in general). And when the operation portion (finger, hand and the like) of the operator M is analyzed on the basis of the light-receiving pattern at the light-receiving pattern analysis portion 230, the information in the database 260 may be referred to in the analysis.

(2-5-4) Application to Other Service Usages:

Similarly to the description in the variation of the above (1-5-4), the second embodiment may also be applied to the operations such as reception/guidance operations and other service businesses in which an operator refers to a manual, documents and the like or uses electronic files in general in addition to the servicing related businesses. Further, all the operations carried out on usual operating equipment, personal computers and the like, numeral/character input, e-mail transmission/receiving can be used instead of keyboard operation on a personal computer or mobile equipment. Moreover, application to entertainment such as game equipment, game facilities and the like is possible and the same effect can be also obtained in this case.

Other than those mentioned above, methods of the embodiments and each variation may be combined as appropriate for use.

Though not specifically exemplified, the present invention should be put into practice with various changes made in a range not departing from its gist.

What is claimed is:

1. An operating apparatus comprising:
a mounting device mounted on a body of an operator;
at least one light emitting device configured to emit predetermined irradiation light, provided at said mounting device;
a plurality of light receiving devices configured to receive reflection light or scattering light or transmission light of said irradiation light, provided at said mounting device; and
a signal output portion configured to output an operation signal corresponding to an operation state of the operator on the basis of a combination of light-receiving results at said plurality of light receiving devices.

2. The operating apparatus according to claim 1, wherein:
said mounting device is mounted on said body so that said irradiation light emitted from said light emitting device is irradiated to a part of said body;
said plurality of light receiving devices receive scattering light or transmission light at an irradiation portion of said irradiation light irradiated to a part of said body; and
said signal output portion outputs the operation signal corresponding to an operation state of the operator on the basis of a combination of light receiving results of said scattering light or said transmission light at said plurality of light receiving devices.

3. The operating apparatus according to claim 1, wherein:
said mounting device is mounted on a wrist of said operator;
said light emitting device emits said predetermined irradiation light to the side of the back of hand of said operator;
said plurality of light receiving devices receive said reflection light or said scattering light at a finger part of said operator from the side of said back of hand; and
said signal output portion outputs the operation signal corresponding to an operation state of the operator on the basis of a combination of light receiving results of said reflection light or said scattering light at said plurality of light receiving devices.

4. The operating apparatus according to claim 3, wherein:
said light receiving devices are arranged capable of receiving reflection light or scattering light of said irradiation light at least at a palm of said operator.

5. The operating apparatus according to claim 4, wherein:
said light receiving devices are arranged so that the focus positions of light receiving devices are in the vicinity of the palm position of said operator.

6. The operating apparatus according to claim 3, wherein:
said light receiving devices are arranged capable of receiving reflection light or scattering light of said irradiation light at least at the finger part of said operator.

7. The operating apparatus according to claim 6, wherein:
said light receiving devices are arranged capable of receiving the reflection light of said irradiation light reflected at a reflecting body provided at the finger of said operator.

8. The operating apparatus according to claim 1, further comprising:
a pattern detecting portion configured to detect said light emitting device and at least one of said light receiving devices that received said irradiation light from the light emitting device or reflection light or scattering light of said irradiation light as a light receiving pattern, wherein
said signal output portion outputs said operation signal on the basis of the light receiving pattern detected by said pattern detecting portion.

9. The operating apparatus according to claim 8, wherein:
said pattern detecting portion obtains said light receiving pattern from a differential signal between a light receiving result at said plurality of light receiving devices at non light emission of said light emitting devices and a light receiving result at said plurality of light receiving devices at light emission of said light emitting devices.

10. The operating apparatus according to claim 1, wherein:
said at least one light emitting device and said plurality of light receiving devices are arranged substantially annularly with respect to said mounting device.

11. The operating apparatus according to claim 10, further comprising a plurality of light-emitting/light-receiving device groups including one said light emitting device and at least one said light receiving device, wherein
each of the plurality of light-emitting/light-receiving device groups is arranged on said mounting device in rotation symmetry to each other.

12. The operating apparatus according to claim 11, further comprising:
a comparing portion for position detection configured to compare a light receiving pattern detected by said pattern detecting portion and a reference position light receiving pattern set in advance; and
a position detecting portion configured to detect a position of the operating apparatus along a rotating direction on the basis of a comparison result by said comparing portion for position detection, wherein
said signal output portion outputs said operation signal on the basis of the light receiving pattern detected by said pattern detecting portion and a position detection result of said position detecting portion.

13. The operating apparatus according to claim 12, wherein:
said comparing portion for position detection carries out said comparison by checking matching or non-matching between said detected light receiving pattern and said reference position light receiving pattern, by quantifying similarity between said detected light receiving pattern and said reference position light receiving pattern by a predetermined function and selecting a case not less than a predetermined value, or by a method of neural network using a weighted repeat calculation, and
said operating apparatus further comprises a determination comparing device provided with a learning mode in which parameters required for determination are obtained on the basis of a teacher signal and a determination mode in which a determination is made from the parameters and obtained data and having a memory portion in which said parameters are stored.

14. The operating apparatus according to claim 12, further comprising a correcting portion configured to correct a light receiving pattern detected by said pattern detecting portion according to a position detection result of said position detecting portion, wherein
said signal output portion outputs said operation signal on the basis of a light receiving pattern corrected by said correcting portion.

15. The operating apparatus according to claim 14, further comprising a first attitude calculating portion configured to calculate an attitude of an operation portion of said operator or a change mode of the attitude on the basis of a light receiving pattern corrected by said correcting portion, wherein
said signal output portion outputs said attitude or the change mode of said attitude calculated by said first attitude calculating portion as said operation signal.

16. The operating apparatus according to claim 15, further comprising a first comparing portion for attitude detection configured to compare a reference attitude light receiving pattern set according to living body information distribution corresponding to a predetermined reference attitude of an operation portion of the operator and a light receiving pattern corrected by said correcting portion, wherein
said first attitude calculating portion calculates said attitude or said change mode of the attitude according to a comparison result at said first comparing portion for attitude detection.

17. The operating apparatus according to claim 16, wherein:
said first comparing portion for attitude detection carries out said comparison by checking matching or non-matching between said detected light receiving pattern and said reference attitude light receiving pattern, by quantifying similarity between said detected light receiving pattern and said reference attitude light receiving pattern by a predetermined function and selecting a case not less than a predetermined value, or by a method of neural network using a weighted repeat calculation.

18. The operating apparatus according to claim 8, wherein:
said light receiving device and said pattern detecting portion are configured so that a movement of at least one finger of said operator can be detected as said light receiving pattern.

19. The operating apparatus according to claim 18, wherein:
said light receiving device and said pattern detecting portion are configured so that movements of five fingers of said operator can be detected as said light receiving pattern.

20. The operating apparatus according to claim 8, further comprising a second attitude calculating portion configured to calculate an attitude of a finger part of said operator or a change mode in the attitude on the basis of a light receiving pattern detected by said pattern detecting portion, wherein
said signal output portion outputs said attitude or said change mode of the attitude calculated by said second attitude calculating portion as said operation signal.

21. The operating apparatus according to claim 20, further comprising a second comparing portion for attitude detection configured to compare a reference attitude light receiving pattern set according to living body information distribution corresponding to a predetermined reference attitude of a finger part of said operator and a light receiving pattern detected by said pattern detecting portion, wherein
said second attitude calculation portion calculates said attitude or said change mode of the attitude according to a comparison result at said second comparing portion for attitude detection.

22. The operating apparatus according to claim 21, wherein:
said second comparing portion for attitude detection carries out said comparison by checking matching or non-matching between said detected light receiving pattern and said reference attitude light receiving pattern, by quantifying similarity between said detected light receiving pattern and said reference attitude light receiving pattern by a predetermined function and selecting a case not less than a predetermined value, or by a method of neural network using a weighted repeat calculation.

23. The operating apparatus according to claim 22, further comprising a determination comparing device provided with a learning mode in which parameters required for determination are obtained on the basis of a teacher signal and a determination mode in which a determination is made from the parameters and obtained data and having a memory portion in which said parameters are stored.

24. The operating apparatus according to claim 8, further comprising a first selection instruction determining portion configured to determine whether a selection instruction has been inputted or not, said selection instruction being to select a plurality of modes set in relation to attitude recognition of a finger part of said operator on the basis of said operation signal.

25. The operating apparatus according to claim 24, wherein:
said first selection instruction determining portion includes a first comparing portion for mode instruction configured to compare said light receiving pattern detected by said pattern detecting portion and a light receiving pattern for mode instruction set in advance and determines whether said selection instruction has been inputted or not according to a comparison result of said first comparing portion for mode instruction.

26. The operating apparatus according to claim 8, further comprising a start instruction determining portion configured to determine whether a start instruction to start output of said operation signal by said signal output portion has been inputted or not, wherein
said signal output portion outputs said operation signal when determination at said start instruction determining portion is satisfied.

27. The operating apparatus according to claim 26, wherein:
said start instruction determining portion includes a comparing portion for start instruction detection configured to compare said light receiving pattern detected by said pattern detecting portion and a light receiving pattern for start instruction set in advance and determines on whether said start instruction has been inputted or not according to a comparison result of said comparing portion for start instruction detection.

28. The operating apparatus according to claim 8, further comprising a stop instruction determining portion configured to determine whether a stop instruction to stop output of said operation signal by said signal output portion has been inputted or not, wherein
said signal output portion stops output of said operation signal when the determination by said stop instruction determining portion is satisfied.

29. The operating apparatus according to claim 28, wherein:
said stop instruction determining portion includes a comparing portion for stop instruction detection configured to compare said light receiving pattern detected by said pattern detecting portion and a light receiving pattern for stop instruction set in advance and determines whether said stop instruction has been inputted or not according to a comparison result of said comparing portion for stop instruction detection.

30. The operating apparatus according to claim 2, wherein:
said light emitting device emits said irradiation light with a wavelength included in a range from visible light band to near infrared light band, and
said light receiving device receiving said irradiation light with the wavelength included in the visible light band is arranged so that the focus position of the light receiving device is in the vicinity of the back of hand of said operator.

31. The operating apparatus according to claim 2, wherein:
said light emitting devices are provided in plural; and those plurality of light emitting devices emit the same irradiation light included in the near infrared band, respectively, and
said operating apparatus further comprises a time-difference light emission control portion configured to sequentially emit light of said plurality of light emitting devices with a time difference.

32. The operating apparatus according to claim 2, wherein:
said light emitting devices are provided in plural; and those plurality of light emitting devices emit irradiation light with a plurality of wavelength, at least one of which is included in the near infrared band, and
said operating apparatus further comprises:
a simultaneous light emission control portion configured to simultaneously emit light of said plurality of light emitting devices; and
a filter device configured to separate said irradiation light by predetermined wavelength band, said irradiation light simultaneously emitted from said plurality of light emitting devices on the basis of control of said simultaneous light emission control portion and received by said plurality of light receiving devices.

33. An operating system comprising:
an operating apparatus having a mounting device mounted on a body of an operator; at least one light emitting device configured to emit predetermined irradiation light, provided at said mounting device; a plurality of light receiving devices configured to receive reflection light or scattering light or transmission light of said irradiation light, provided at said mounting device; and a signal output portion configured to output an operation signal corresponding to an operation state of the operator on the basis of a combination of light-receiving results at said plurality of light receiving devices; and
a controller having an attitude calculating portion configured to calculate an attitude of an operation portion of said operator or a change mode in the attitude on the basis of a light receiving pattern obtained from said operation signal inputted from said signal output portion.

34. The operating system according to claim 33, wherein:
in said operating apparatus,
said mounting device is mounted on said body so that said irradiation light emitted from said light emitting device is irradiated to a part of said body;
said plurality of light receiving devices receive scattering light or transmission light at an irradiation portion of said irradiation light irradiated to the part of said body is provided;
a pattern detecting portion configured to detect said light emitting device and at least one said light receiving device that received said irradiation light from the light emitting device as a light receiving pattern is provided;
said signal output portion outputs said operation signal corresponding to an operation state of said operator on the basis of said light receiving pattern detected by said pattern detecting portion; and
said attitude calculating portion of said controller is a first attitude calculating portion configured to calculate an attitude of an operation portion of said operator or a change mode of the attitude on the basis of said light receiving pattern obtained from said operation signal inputted from said signal output portion.

35. The operating system according to claim 34, wherein:
said controller has a first comparing portion for calculation configured to compare a reference attitude light receiving pattern set according to living body information distribution corresponding to a predetermined attitude of an operation portion of said operator and said obtained light receiving pattern; and
said first attitude calculating portion calculates said attitude or the change mode of said attitude according to a comparison result of said first comparing portion for calculation.

36. The operating system according to claim 33, wherein:
in said operating apparatus,
said mounting device is mounted on a wrist of said operator;
said light emitting device emits said predetermined irradiation light to the side of the back of hand of said operator;
said plurality of light receiving devices receive said reflection light or scattering light at a finger part of said operator from the side of said back of hand;
a pattern detecting portion configured to detect said light emitting device and at least one said light receiving device that receives reflection light or scattering light of said irradiation light from the light emitting device as a light receiving pattern is provided;
said signal output portion outputs said operation signal corresponding to an operation state of the finger part of said operator on the basis of said light receiving pattern detected by said pattern detecting portion; and
said attitude calculating portion of said controller is a second attitude calculating portion configured to calculate an attitude or a change mode of the attitude of the finger part of said operator on the basis of said light receiving pattern obtained from said operation signal inputted from said signal output portion.

37. The operating system according to claim 36, wherein:
said controller has a second comparing portion for calculation configured to compare a reference attitude light receiving pattern set according to living body information distribution corresponding to a predetermined attitude of the finger part of said operator and said obtained light receiving pattern; and
said second attitude calculating portion calculates said attitude or said change mode of said attitude according to a comparison result of said second comparing portion for calculation.

38. The operating system according to claim 36, wherein:
said controller includes a second selection instruction determining portion configured to determine if a selection instruction to select a plurality of modes set in relation to attitude recognition of the finger part of the operator on the basis of said operation signal has been inputted from said operating apparatus or not.

39. The operating system according to 38, wherein:
said second selection instruction determining portion of said controller includes a second comparing portion for mode instruction configured to compare said light receiving pattern detected by said pattern detecting portion and a light receiving pattern for mode instruction set in advance and determines whether said selection instruction has been inputted or not according to a comparison result of said second comparing portion for mode instruction.
